(19) United States
(12) Patent Application Publication
(10) Pub. No.: US 2026/0181939 A1
(43) Pub. Date: Jun. 25, 2026

(54) SEMICONDUCTOR DEVICE AND METHODS OF FORMING THE SAME

(71) Applicant: Taiwan Semiconductor Manufacturing Co., Ltd., Hsinchu (TW)

(72) Inventors: Bang-Ting Yan, Hsinchu (TW); Heng-Wen Ting, Pingtung (TW); Chien-I Kuo, Zhubei City (TW); Ming-Hua Yu, Hsinchu (TW); Chii-Horng Li, Zhubei City (TW)

(21) Appl. No.: 19/001,304

(22) Filed: Dec. 24, 2024

(51) Int. Cl. H10D 30/00; H10D 30/01

(52) U.S. Cl. CPC H10D 30/502; H10D 30/0191

(57) ABSTRACT

In an embodiment, a method includes: forming a plurality of semiconductor layers over a substrate, the plurality of semiconductor layers comprising alternating first semiconductor layers and second semiconductor layers; patterning the plurality of the semiconductor layers into a fin; etching the fin to form a first recess; forming an epitaxial region in the first recess, forming the epitaxial region comprising: forming first epitaxial layers over sidewalls of the second semiconductor layers; forming second epitaxial layers over the first epitaxial layers; forming shape fixing layers over the second epitaxial layers; and forming a bulk epitaxial layer over the shape fixing layers; removing the first semiconductor layers to form a second recess between the second semiconductor layers; and forming a gate structure in the second recess.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional issues arise that may be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIGS. 2-22C illustrate varying views of intermediary steps of manufacturing a nano-FET transistor, in accordance with some embodiments.

FIGS. 23A-25B illustrate views of intermediary steps of manufacturing various nano-FET transistors, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In various embodiments, transistors are formed over a semiconductor substrate. The transistors may be nano-FETs, although any suitable types of transistors may utilize the embodiments disclosed herein. In accordance with some embodiments, a fin is formed over the semiconductor substrate, a dummy gate structure is formed across the fin, and the fin may is etched to form a source/drain recess adjacent to the dummy gate structure. An epitaxial source/drain region is then formed in the source/drain recess by forming a plurality of epitaxial sub-layers. For example, a first epitaxial layer is grown along semiconductor material in the recess, and a second epitaxial layer is grown over the first epitaxial layer. A shape fixing layer is then epitaxially grown over the second epitaxial layer. The shape fixing layer has a greater rigidity and provides structural support to the underlying epitaxial layers. In addition, the shape fixing layer serves as a scaffolding to provide structural support for subsequently for epitaxial layers of the epitaxial source/drain region. The epitaxial source/drain region is formed to create a desired strain in portions of the fin which will serve as channel regions of the transistor. The shape fixing layer helps to prevent thermal reflow of the epitaxial source/drain region during process steps that involve elevated temperatures. By preventing thermal reflow, the epitaxial source/drain region is able to maintain the desired strain in the channel regions of the transistor, thereby improving yield and performance of the transistor.

Embodiments are described below in a particular context, a die comprising nano-FETs. In particular, the embodiments may be described with respect to p-type nano-FETs. Various embodiments may be applied, however, to dies comprising other types of transistors (e.g., stacking transistors, or the like) in lieu of or in combination with the nano-FETs. In addition, the embodiments may be applied to n-type nano-FETs wherever applicable.

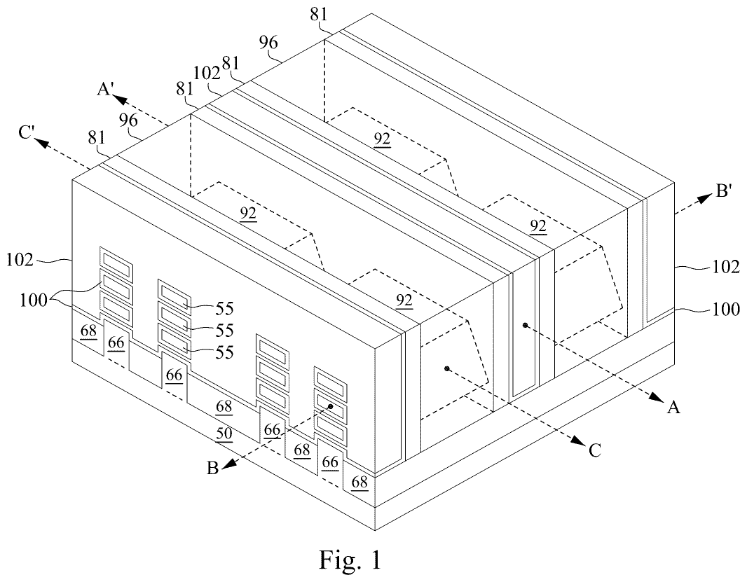

FIG. 1 illustrates an example of nano-FETs (e.g., nanowire FETs, nanosheet FETs (Nano-FETs), or the like) in a three-dimensional view, in accordance with some embodiments. Certain features are simplified and/or omitted in FIG. 1 for ease of illustration. The nano-FETs comprise nanostructures 54 (e.g., nanosheets, nanowires, or the like) over fins 66 on a substrate 50 (e.g., a semiconductor substrate), wherein the nanostructures 54 act as channel regions for the nano-FETs. The nanostructure 54 may include p-type nanostructures, n-type nanostructures, or a combination thereof. Shallow trench isolation (STI) regions 68 (also referred to as STI structures or STI regions) are disposed between adjacent fins 66, which may protrude above and from between neighboring STI regions 68. Although the STI regions 68 are described/illustrated as being separate from the substrate 50, as used herein, the term “substrate” may refer to the semiconductor substrate alone or a combination of the semiconductor substrate and the isolation regions. Additionally, although a bottom portion of the fins 66 are illustrated as being single, continuous materials with the substrate 50, the bottom portion of the fins 66 and/or the substrate 50 may comprise a single material or a plurality of materials. In this context, the fins 66 refer to the portions extending between the neighboring STI regions 68.

Gate dielectric layers 100 are over top surfaces of the fins 66 and along top surfaces, sidewalls, and bottom surfaces of the nanostructures 54. Gate electrodes 102 are over the gate dielectric layers 100. Epitaxial source/drain regions 92 are disposed on the fins 66 on opposing sides of the gate dielectric layers 100 and the gate electrodes 102. Source/drain region(s) 92 may refer to a source or a drain, individually or collectively dependent upon the context.

FIG. 1 further illustrates reference cross-sections that are used in later figures. Cross-section A-A′ is along a longitudinal axis of a gate electrode 102 and in a direction, for example, perpendicular to the direction of current flow between the epitaxial source/drain regions 92 of a nano-FET. Cross-section B-B′ is perpendicular to cross-section A-A′ and is parallel to a longitudinal axis of a fin 66 of the nano-FET and in a direction of, for example, a current flow between the epitaxial source/drain regions 92 of the nano-FET. Cross-section C-C′ is parallel to cross-section A-A′ and extends through epitaxial source/drain regions of the nano-FETs. Subsequent figures refer to these reference cross-sections for clarity.

Some embodiments discussed herein are discussed in the context of nano-FETs formed using a gate-last process. In other embodiments, a gate-first process may be used. Also, some embodiments contemplate aspects used in planar devices, such as planar FETs or in fin field-effect transistors (FinFETs).

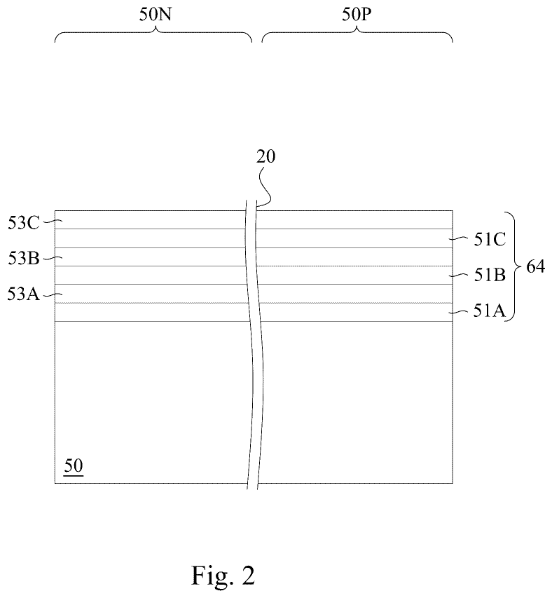

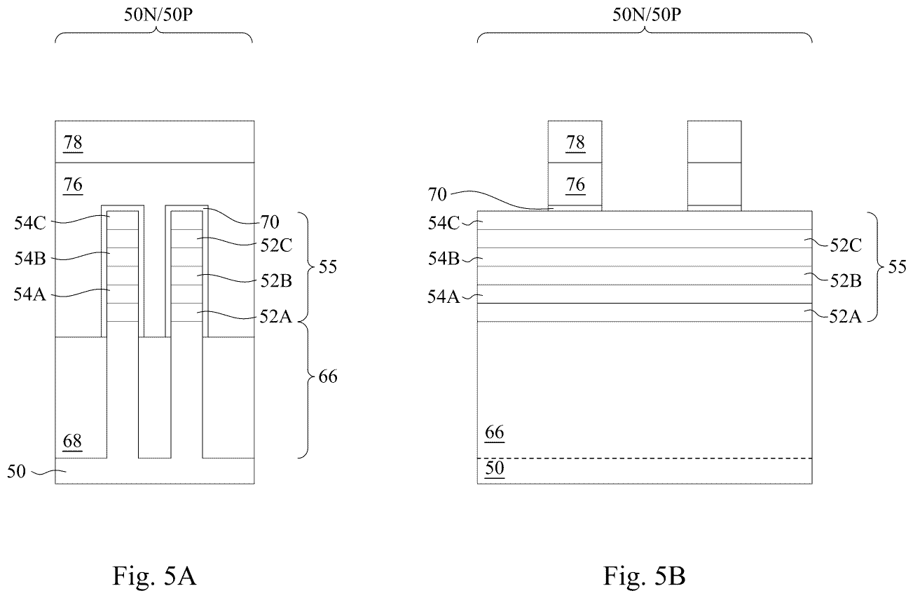

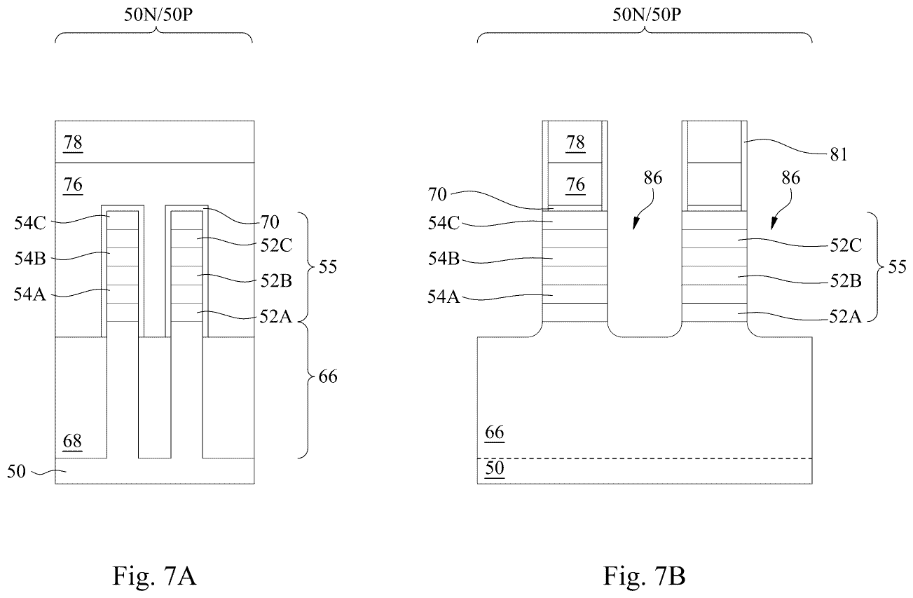

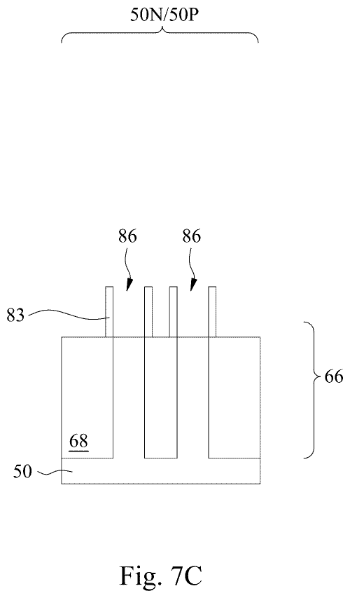

FIGS. 2 through 22C and 23A through 25B are cross-sectional views of intermediate stages in the manufacturing of various nano-FETs, in accordance with some embodiments. FIGS. 2, 3, 4, 5A, 6A, 7A, 8A, 9A, 10A, 11A, 12A, 13A, 14A, 15A, 16A, 17A, 18A, 19A, 20A, 21A, and 22A illustrate reference cross-section A-A′ illustrated in FIG. 1. FIGS. 5B, 6B, 7B, 8B, 9B, 10B, 10C, 10D, 11B, 12B, 13B, 14B, 15B, 16B, 17B, 18B, 19B, 19C, 20B, 21B, 22B, and 23A-25B illustrate reference cross-section B-B′ illustrated in FIG. 1. FIGS. 7C, 11C, 11D, 12C, 12D, 13C, 13D, 14C, 14D, 15C, 15D, 20C, 21C, and 22C illustrate reference cross-section C-C′ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided. Subsequent figures describe processing steps that may be performed in either the n-type region 50N or the p-type region 50P unless otherwise noted.

Further in FIG. 2, a multi-layer stack 64 is formed over the substrate 50. The multi-layer stack 64 includes alternating layers of first semiconductor layers 51A-C (collectively referred to as first semiconductor layers 51) and second semiconductor layers 53A-C (collectively referred to as second semiconductor layers 53). For purposes of illustration and as discussed in greater detail below, the first semiconductor layers 51 will be removed and the second semiconductor layers 53 will be patterned to form channel regions of nano-FETs in both the n-type region 50N and the p-type region 50P. Nevertheless, in some embodiments, the second semiconductor layers 53 may be removed and the first semiconductor layers 51 may be patterned to form channel regions of nano-FETs in both the n-type region 50N and the p-type region 50P. For example, the channel regions in both the n-type region 50N and the p-type region 50P may have a same material composition (e.g., silicon, or another semiconductor material) and be formed simultaneously.

In other embodiments, the first semiconductor layers 51 may be removed and the second semiconductor layers 53 may be patterned to form channel regions of nano-FETs in the p-type region 50P, and the second semiconductor layers 53 may be removed and the first semiconductor layers 51 may be patterned to form channel regions of nano-FETs in the n-type region 50N. In still other embodiments, the first semiconductor layers 51 may be removed and the second semiconductor layers 53 may be patterned to form channel regions of nano-FETs in the n-type region 50N, and the second semiconductor layers 53 may be removed and the first semiconductor layers 51 may be patterned to form channel regions of nano-FETs in the p-type region 50P. In such embodiments, the channel regions of the n-type region 50N may have a different material composition than the channel regions of the p-type region 50P. The first semiconductor layers 51 and the second semiconductor layers 53 may be selectively removed from each of the n-type region 50N and p-type region 50P through additional masking and etching steps. For example, the channel regions of the n-type region 50N may be silicon channel regions while the channel regions of the p-type region 50P may be silicon germanium channel regions.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like.

In various embodiments, the first semiconductor layers 51 may be formed of a first semiconductor material, such as silicon germanium, or the like, and the second semiconductor layers 53 may be formed of a second semiconductor material, such as silicon, silicon carbon, or the like. The first semiconductor materials and the second semiconductor materials may be materials having a high-etch selectivity to one another. As such, the first semiconductor layers 51 of the first semiconductor material may be removed without significantly removing the second semiconductor layers 53 of the second semiconductor material, thereby allowing the second semiconductor layers 53 to be patterned to form channel regions of the nano-FETs.

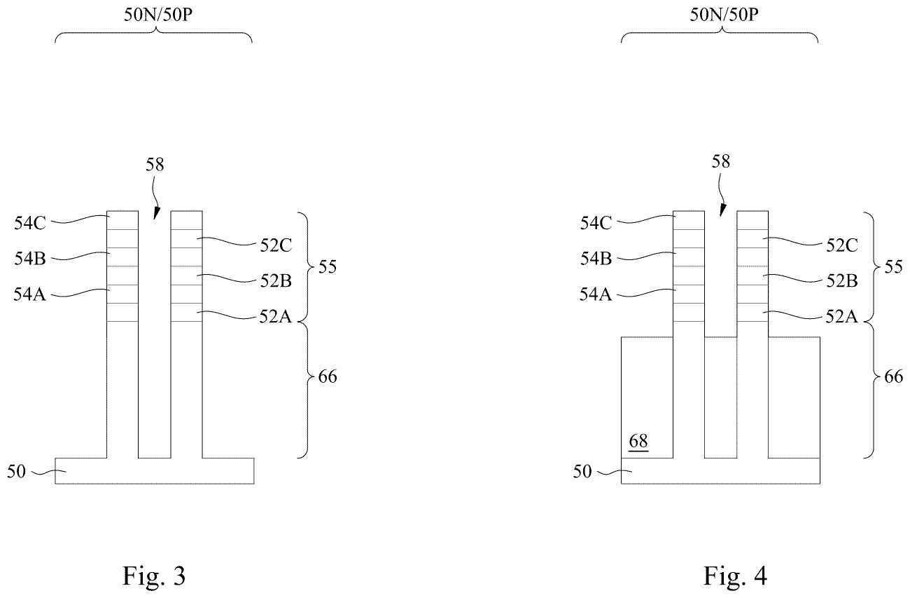

Referring now to FIG. 3, fins 66 are formed in the substrate 50 and nanostructures 55 are formed in the multi-layer stack 64 (shown in FIG. 2), in accordance with some embodiments. In some embodiments, the nanostructures 55 and the fins 66 may be formed in the multi-layer stack 64 (shown in FIG. 2) and the substrate 50, respectively, by etching trenches 58 in the multi-layer stack 64 (shown in FIG. 2) and the substrate 50. The etching may be any acceptable etch process, such as a reactive ion etch (RIE), neutral beam etch (NBE), the like, or a combination thereof. The etching may be anisotropic. During the etching process, a hard mask may be used to define a pattern of the fins 66 and the nanostructures 55. The hard mask may comprise any suitable insulating material, such as an oxide, a nitride, and oxynitride, and oxycarbonitride, or the like. In some embodiments (not separately illustrated), the hard mask may be a multi-layer structure. The hard mask may be formed over the nanostructures 55 using an acceptable process(es) such as thermal oxidation, physical vapor deposition (PVD), CVD, ALD, combinations thereof, or the like.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, a sacrificial layer is formed over a substrate and patterned using a photolithography process. Spacers are then formed alongside the patterned sacrificial layer using a self-aligned process. The sacrificial layer is then removed, and the remaining spacers may then be used to pattern the fins 66 and the nanostructures 55.

Forming the nanostructures 55 by etching the multi-layer stack 64 (shown in FIG. 2) may further define first nanostructures 52A-C (collectively referred to as the first nanostructures 52) from the first semiconductor layers 51 and define second nanostructures 54A-C (collectively referred to as the second nanostructures 54) from the second semiconductor layers 53. The first nanostructures 52 and the second nanostructures 54 may further be collectively referred to as the nanostructures 55.

FIG. 3 illustrates the fins 66 having substantially equal widths for illustrative purposes. In some embodiments, widths of the fins 66 in the n-type region 50N may be greater or thinner than the fins 66 in the p-type region 50P. Further, while FIG. 3 illustrates each of the fins 66 and the nanostructures 55 as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66 to fill the trenches 58. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along a surface of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that upper portions of fins 66 protrude from between neighboring STI regions 68. Further, the top surfaces of the STI regions 68 may be flat surfaces as illustrated, convex surfaces, concave surfaces (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric (dHF) acid may be used. Thereafter, an optional hard mask (not separately illustrated) may then be formed over the top surfaces of the STI regions 68 to cover the STI regions 68. The hard mask may be made of a nitride or other material that has etch selectivity to the STI regions 68 (e.g., etch selectivity to a fill material of the STI regions 68).

Further in FIG. 4, appropriate wells (not separately illustrated) may be formed in the first semiconductor layers 51, the second semiconductor layers 53, and/or the substrate 50. In embodiments with different well types, different implant steps for the n-type region 50N and the p-type region 50P may be achieved using a photoresist or other masks (not separately illustrated). For example, a photoresist may be formed over structures in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over structures in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the implantation process may be performed on the substrate 50 prior to forming the first semiconductor layers 51 and the second semiconductor layers 53. Subsequently, the grown materials of the first semiconductor layers 51 and/or the semiconductor layers 53 may be in situ doped during growth. Alternatively, the implantation process may be performed on one or more of the first semiconductor layers 51 and/or the second semiconductor layers 53.

In FIGS. 5A and 5B, dummy gates 76 are formed over and along sidewalls of the nanostructures 55 and the fin 66. To form the dummy gates 76, first, a dummy dielectric layer is formed on the fins 66 and/or the nanostructures 55. The dummy dielectric layer may be made of silicon oxide, silicon nitride, a combination thereof, or the like, and may be deposited or thermally grown according to acceptable techniques. A dummy gate layer is formed over the dummy dielectric layer, and a mask layer is formed over the dummy gate layer. The dummy gate layer may be deposited over the dummy dielectric layer and then planarized, such as by a CMP. The mask layer may be deposited over the dummy gate layer. The dummy gate layer may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer may be deposited by physical vapor deposition (PVD), CVD, sputter deposition, or other techniques for depositing the selected material. The dummy gate layer may be made of other materials that have a high etching selectivity from the etching of isolation regions. The mask layer may include, for example, silicon nitride, silicon oxynitride, or the like.

Subsequently, the mask layer may be patterned using acceptable photolithography and etching techniques to form masks 78. The pattern of the masks 78 then may be transferred to the dummy gate layer and to the dummy dielectric layer to form dummy gates 76 and dummy gate dielectrics 70, respectively. The dummy gates 76 cover respective channel regions of the fins 66. The pattern of the masks 78 may be used to physically separate each of the dummy gates 76 from adjacent dummy gates 76. The dummy gates 76 may also have a lengthwise direction substantially perpendicular to the lengthwise direction of respective fins 66. It is noted that the dummy gate dielectrics 70 is shown covering only the fins 66 and the nanostructures 55 for illustrative purposes only. In some embodiments, the dummy gate dielectrics 70 may be deposited such that the dummy gate dielectrics 70 covers the STI regions 68, such that the dummy gate dielectrics 70 extends between the dummy gates 76 and the STI regions 68.

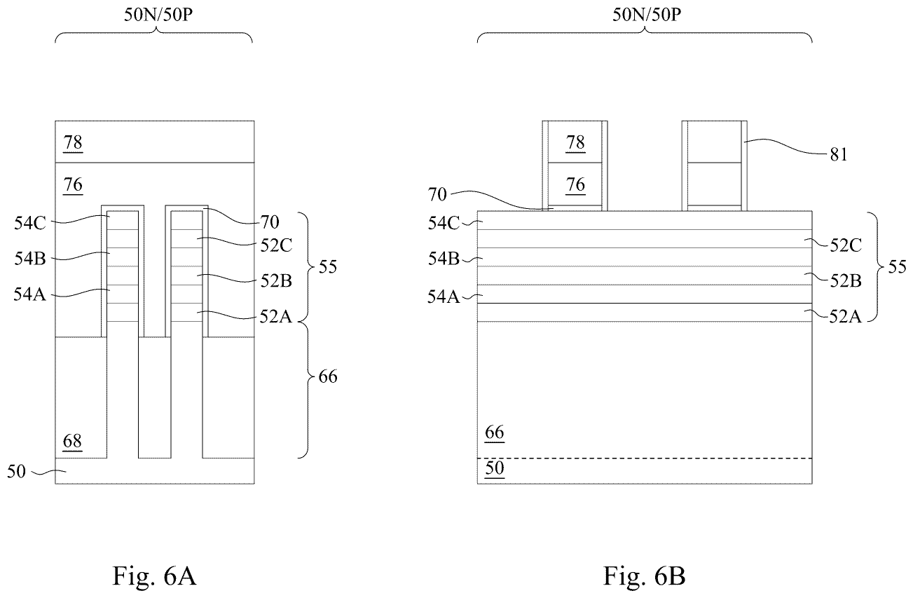

In FIGS. 6A and 6B, gate spacers 81 are formed over the nanostructures 55 and the STI regions 68, on exposed sidewalls of the masks 78 (if present), the dummy gates 76, and the dummy gate dielectrics 70. The gate spacers 81 may be formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other insulation materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gates 76 (thus forming the gate spacers 81). As subsequently described in greater detail, the dielectric material(s), when etched, may also have portions left on the sidewalls of the semiconductor fins 66 and/or the nanostructures 55 (thus forming fin spacers 83, see FIG. 7C). After etching, the fin spacers 83 and/or the gate spacers 81 can have straight sidewalls (as illustrated) or can have curved sidewalls (not separately illustrated).

In FIGS. 7A-7C, first recesses 86 are formed in the fins 66, the nanostructures 55, and the substrate 50, in accordance with some embodiments. Epitaxial source/drain regions will be subsequently formed in the first recesses 86. The first recesses 86 may extend through the first nanostructures 52 and the second nanostructures 54, and into the substrate 50. As illustrated in FIG. 7C, top surfaces of the STI regions 68 may be level with bottom surfaces of the first recesses 86. In other embodiments, the fins 66 may be etched such that bottom surfaces of the first recesses 86 are disposed above or below the top surfaces of the STI regions 68. The first recesses 86 may be formed by etching the fins 66, the nanostructures 55, and the substrate 50 using anisotropic etching processes, such as RIE, NBE, or the like. The gate spacers 81, the fin spacers 83, and the masks 78 mask portions of the fins 66, the nanostructures 55, and the substrate 50 during the etching processes used to form the first recesses 86. A single etch process or multiple etch processes may be used to etch each layer of the nanostructures 55 and/or the fins 66. Timed etch processes may be used to stop the etching of the first recesses 86 after the first recesses 86 reach a desired depth.

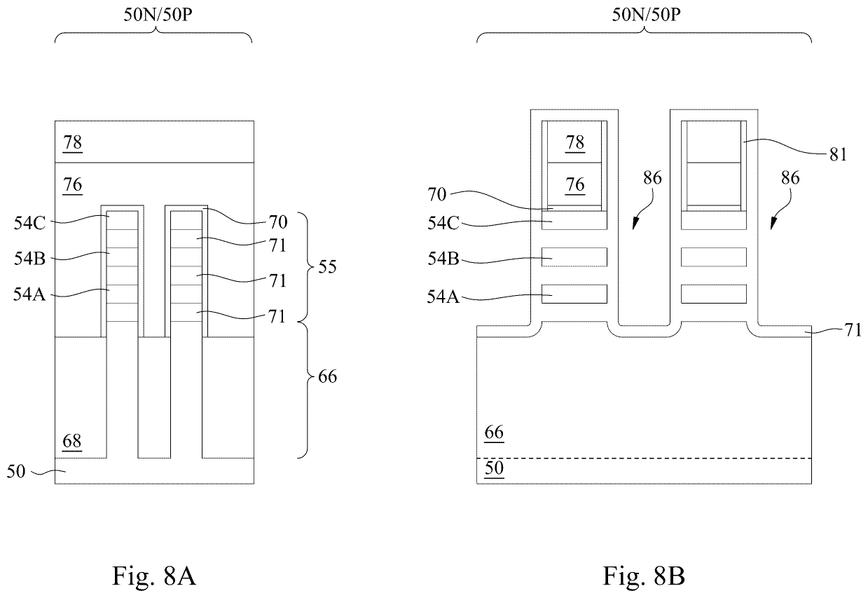

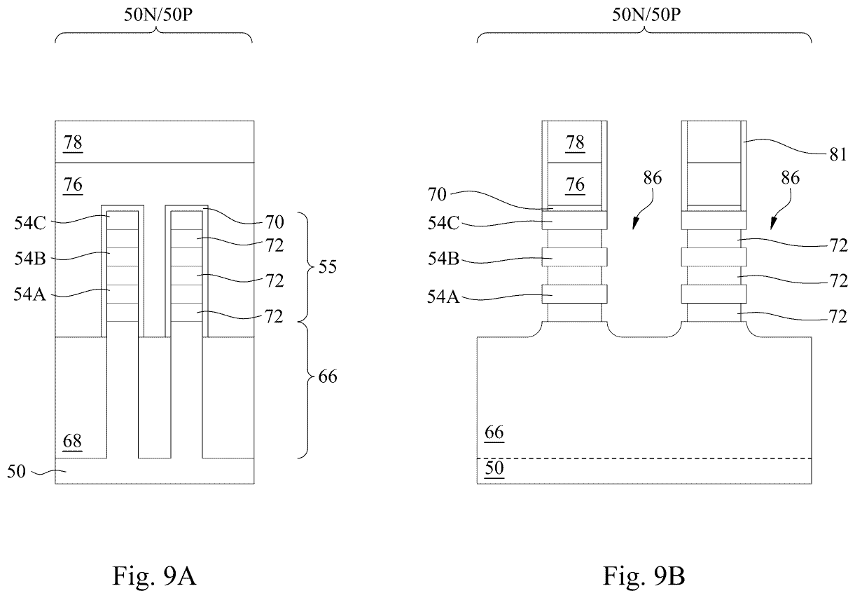

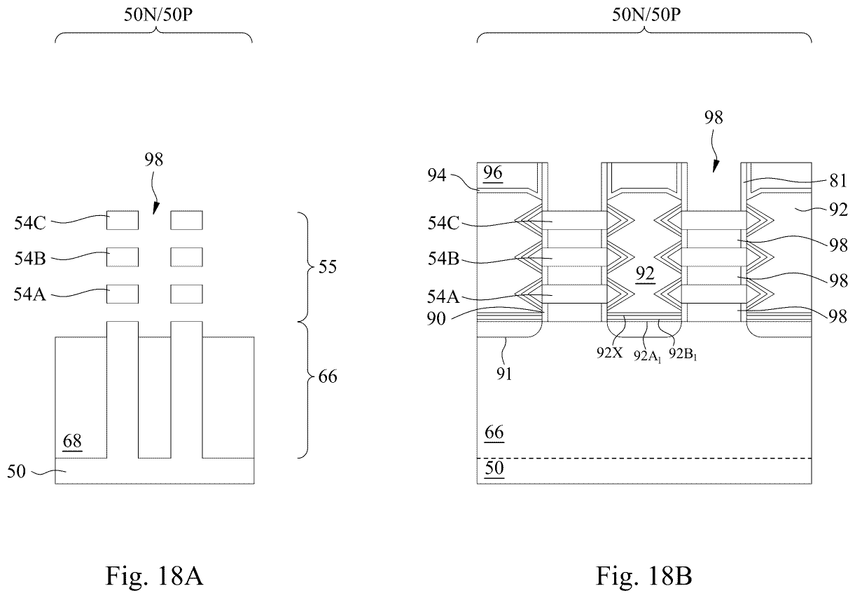

In FIGS. 8A-9B, the first nanostructures 52 are replaced with a sacrificial material 72 (also referred to as disposable oxide interposers (DOI) 72). Replacing the first nanostructures 52 may include etching away the first nanostructures 52 using a suitable etch process, such as an isotropic etch process, that is performed through the first recesses 86 as illustrated by FIGS. 8A-8B. The etch process may be selective to the material of the first nanostructures 52 and remove the first nanostructures 52 without significantly removing the second nanostructures 54 or the semiconductor fins 66. In some embodiments, the second nanostructures 54, particularly corner regions of the second nanostructures 54, may be slightly etched during the removal of the first nanostructures 52. For example, as a result of removing the first nanostructures 52, corners regions of the second nanostructures 54 are spaced farther apart that middle regions of the second nanostructures 54 (see e.g., FIG. 18C). In an embodiment in which the first nanostructures 52 include, e.g., SiGe, and the second nanostructures 54 include, e.g., Si or SiC, a dry etch process with tetramethylammonium hydroxide (TMAH), ammonium hydroxide (NH₄OH), or the like may be used to remove the first nanostructures 52.

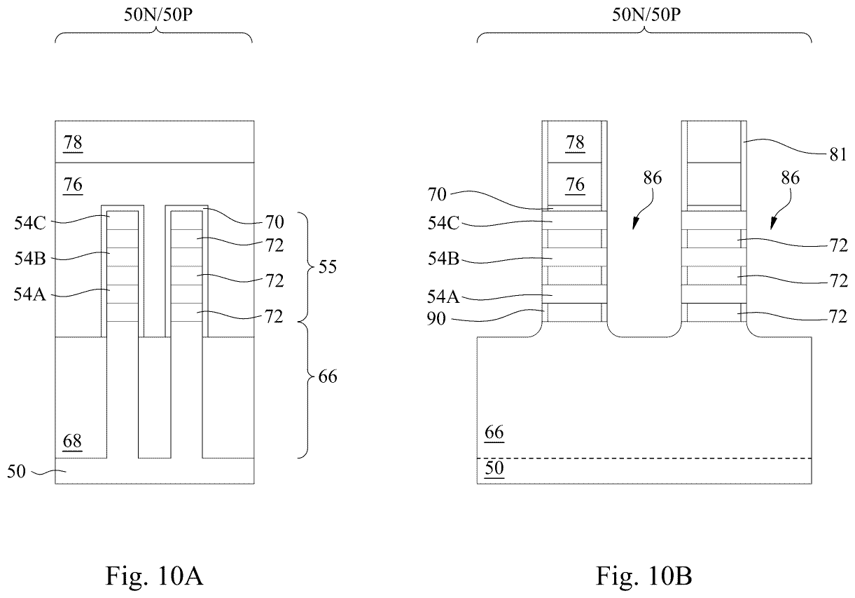

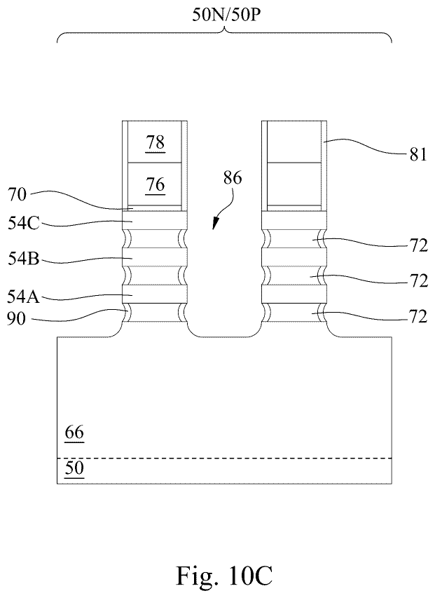

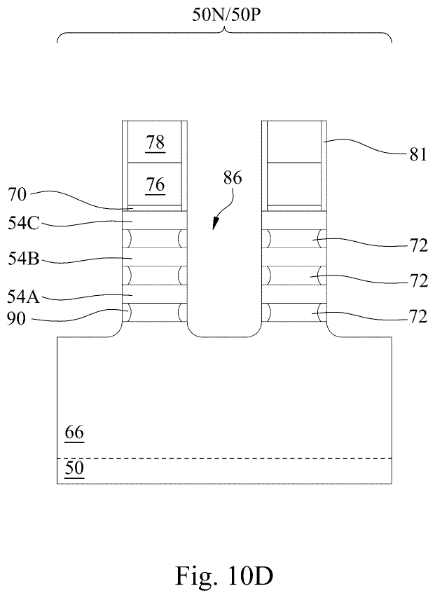

Subsequently, a sacrificial material layer 71 is deposited in the recesses 86 and spaces where the first nanostructures 52 were removed. The sacrificial material layer 71 may be deposited by a conformal deposition process, such as CVD, ALD, or the like. The sacrificial material layer may comprise an insulating material such as silicon oxide (e.g., SiO₂), or the like that can be selectively etched from the second nanostructures 54. In FIGS. 9A-9B, the sacrificial material layer 71 may then be etched to form the sacrificial material 72. The etching may be isotropic or anisotropic. For example, the sacrificial material layer may be etched by a wet etch process using diluted HF, or the like as an etchant. In some embodiments, the etching is performed until sidewalls of the sacrificial material 72 is recessed past sidewalls of the nanostructures 54. Although sidewalls of sacrificial material 72 are illustrated as being straight in FIG. 9B, the sidewalls may be concave or convex (see e.g., FIG. 10C).

Replacing the first nanostructures 52 with the sacrificial material 72 may provide advantages. For example, in subsequent source/drain formation steps, one or more high temperature processes may be performed to, for example, activate the dopants in the source/drain regions. When the material of the first nanostructures 52 (e.g., SiGe) is exposed to high temperatures, germanium intermixing and increased roughness at an interfaces between the nanostructures 52 and 54 may result. Such manufacturing defects may degrade the performance of the resulting transistor devices. For example, when germanium diffuses into the second nanostructures 74, germanium residue may remain in channel regions of the resulting transistor devices, which negatively affects the performance of the channel regions. By replacing the first nanostructures 52 with an insulating material prior to the high temperature processes (e.g., source/drain annealing), manufacturing defects can be reduced and device performance can be improved (e.g., increased current drive, reduced capacitance, and improved short channel effect).

In FIGS. 10A and 10B, inner spacers 90 are formed in the recesses 86 on the sidewalls of the sacrificial material 72. The inner spacers 90 act as isolation features between subsequently formed source/drain regions and a gate structure. As will be discussed in greater detail below, source/drain regions will be formed in the recesses 86, while the sacrificial material 72 will be replaced with corresponding gate structures. The inner spacers 90 may also be used to prevent damage to subsequently formed source/drain regions by subsequent etching processes, such as etching processes used to form gate structures.

The inner spacers 90 may be formed by depositing an inner spacer layer (not separately illustrated) over the structures illustrated in FIGS. 9A and 9B. The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the inner spacers 90. The inner spacer layer may be etched by an anisotropic etching process, such as RIE, NBE, or the like.

Although outer sidewalls of the inner spacers 90 are illustrated as being flush with sidewalls of the second nanostructures 54, the outer sidewalls of the inner spacers 90 may extend beyond or be recessed from sidewalls of the second nanostructures 54 (see e.g., FIG. 10C). Moreover, although the outer sidewalls of the inner spacers 90 are illustrated as being straight in FIG. 10B, the outer sidewalls of the inner spacers 90 may be concave or convex. As an example, FIG. 10C illustrates an embodiment in which sidewalls of the sacrificial material 72 are concave, outer sidewalls of the inner spacers 90 are concave, and the inner spacers 90 are recessed from sidewalls of the second nanostructures 54. Other configurations are also possible. For example, FIG. 10D illustrates an embodiment in which sidewalls of the sacrificial material 72 are concave, outer sidewalls of the inner spacers 90 are straight, and the inner spacers 90 are flush with sidewalls of the second nanostructures 54.

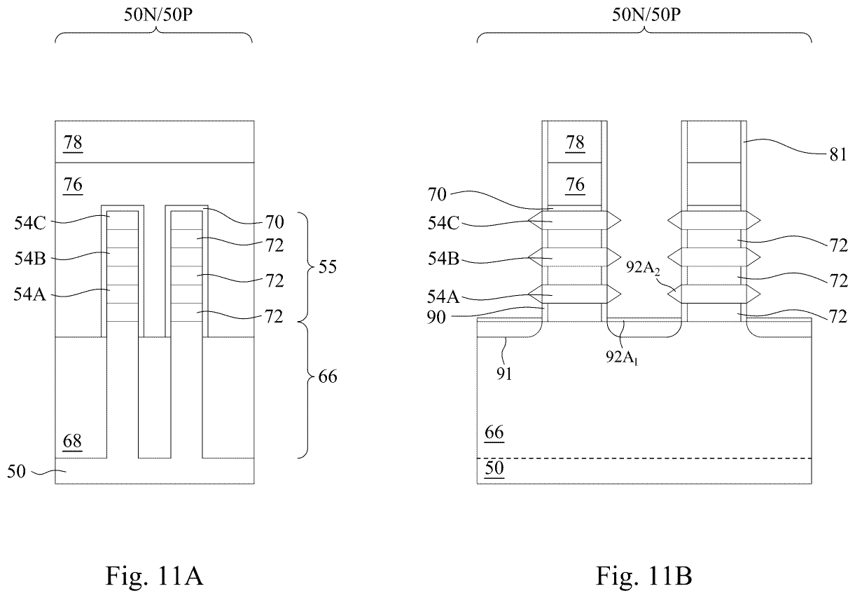

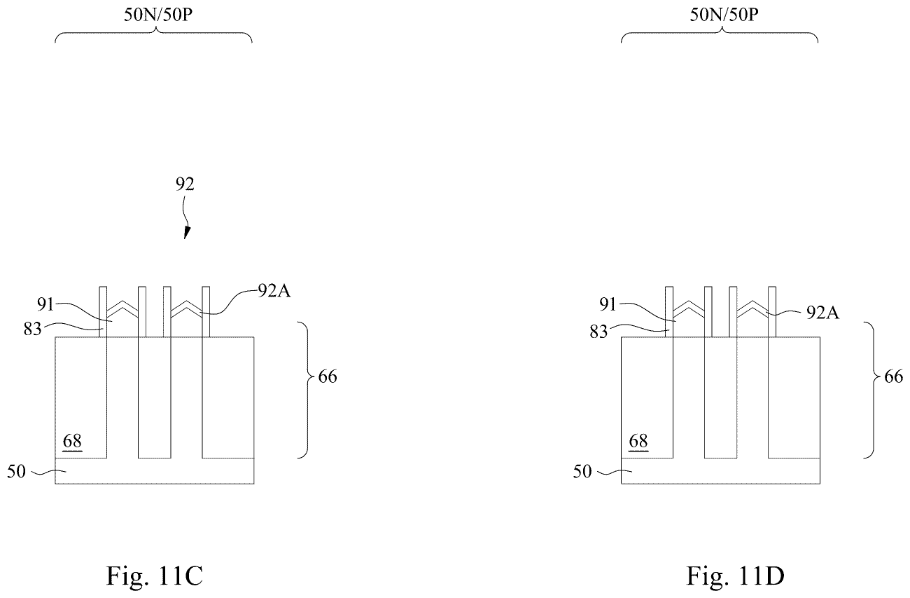

FIGS. 11A-15D illustrate formation of epitaxial source/drain regions 92 in the first recesses 86, in accordance with various embodiments. As discussed in greater detail below, the epitaxial source/drain regions 92 may be formed in a plurality of steps to include a plurality of epitaxial layers of various compositions. In particular, the epitaxial source/drain regions 92 in the p-type region 50P may include a shape fixing layer which helps to maintain the structure and composition of other epitaxial layers, such as underlying epitaxial layers (e.g., sidewall epitaxies). Although formation of the source/drain regions 92 is discussed with respect to both the n-type region 50N and the p-type region 50P, in some embodiments, the shape fixing layers may be included for the source/drain regions 92 in the p-type region 50P and excluded for the source/drain regions 92 in the n-type region 50N.

In some embodiments, the source/drain regions 92 may exert stress on the second nanostructures 54 in the n-type region 50N and/or on the first nanostructures 52 in the p-type region 50P, thereby improving performance. As illustrated, the epitaxial source/drain regions 92 are formed in the first recesses 86 such that each dummy gate 76 is disposed between respective neighboring pairs of the epitaxial source/drain regions 92. In some embodiments, the gate spacers 81 are used to separate the epitaxial source/drain regions 92 from the dummy gates 76 and the inner spacers 90 are used to separate the epitaxial source/drain regions 92 from the sacrificial material 72 by an appropriate lateral distance so that the epitaxial source/drain regions 92 do not short out with subsequently formed gates of the resulting nano-FETs.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the first recesses 86 in the n-type region 50N. The epitaxial source/drain regions 92 may include any acceptable material appropriate for n-type nano-FETs. For example, if the second nanostructures 54 are silicon, the epitaxial source/drain regions 92 in the n-type region 50N may include materials exerting a tensile strain on the second nanostructures 54 (e.g., improving electron mobility), such as silicon, silicon carbide, phosphorous doped silicon carbide, silicon phosphide, or the like.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the first recesses 86 in the p-type region 50P. The epitaxial source/drain regions 92 may include any acceptable material appropriate for p-type nano-FETs. For example, if the second nanostructures 54 are silicon, the epitaxial source/drain regions 92 in the p-type region 50P may include materials exerting a compressive strain on the second nanostructures 54 (e.g., improving hole mobility), such as silicon-germanium, boron doped silicon-germanium, germanium, germanium tin, or the like.

The epitaxial source/drain regions 92, the second nanostructures 54, and/or the substrate 50 may be implanted with dopants to form source/drain regions, similar to the process previously discussed for forming lightly-doped source/drain regions, followed by an anneal. The source/drain regions may have impurity concentrations in various sub-regions ranging from about 1E19 atoms/cm³ to about 1E21 atoms/cm³. The n-type and/or p-type impurities for source/drain regions may be any of the impurities previously discussed. In some embodiments, the epitaxial source/drain regions 92 may be in situ doped during growth.

As discussed below in connection with FIGS. 11A-15D, the epitaxial source/drain regions 92 may comprise one or more semiconductor material layers (e.g., epitaxial layers). For example, the epitaxial source/drain regions 92 may comprise a first epitaxial layer 92A, a second epitaxial layer 92B, a shape fixing layer 92X, a third epitaxial layer 92C, and a fourth epitaxial layer 92D. Any number of semiconductor material layers may be used for the epitaxial source/drain regions 92. Each of these semiconductor material layers may be formed of different semiconductor materials and may be doped to different dopant concentrations. In some embodiments, the first epitaxial layer 92A may have a dopant concentration less than the second epitaxial layer 92B and greater than the third epitaxial layer 92C and the fourth epitaxial layer 92D.

In FIGS. 11A-11D, semiconductor layers 91 may be formed along a bottom of the first recess 86, and first epitaxial layers 92A are formed in the first recesses 86 and over the semiconductor layers 91 (if present). The semiconductor layer 91 may be formed on the fin 66. The semiconductor layer 91 may be formed of a semiconductor material selected from the candidate semiconductor materials of the substrate 50, and may be formed by an epitaxial growth process such as VPE, MBE, or the like. The materials of the semiconductor layer 91 and the substrate 50 may be same or different. For example, the semiconductor layer 91 may be undoped silicon. Timed epitaxial growth processes may be used to grow the semiconductor layers 91 to desired heights. In some embodiments, the semiconductor layers 91 may be separated from the second nanostructures 54. In addition, the semiconductor layers 91 may be substantially level with an upper surface of the fin 66. In other embodiments, the semiconductor layers 91 may be lower than or higher than the upper surface of the fin 66.

The first epitaxial layer 92A may comprise boron-doped silicon (Si:B) or boron-doped silicon germanium (SiGe:B). In regard to some nano-FETs (e.g., p-type nano-FETs), the boron concentration may range from 1E20 atoms/cm³ to 1E21 atoms/cm³. The boron concentration in the first epitaxial layer 92A of n-type nano-FETs may be substantially the same or different. As illustrated, the first epitaxial layer 92A may include a bottom segment 92A₁ along the bottom of the first recesses 86 (e.g., over the semiconductor layer 91) and sidewall segments 92A₂ along sidewalls of the second nanostructures 54.

As illustrated, the first epitaxial layer 92A may include a plurality of the first epitaxial layers 92A which are discontinuous from one another. The first epitaxial layers 92A (e.g., the sidewall segments 92A₂ and the bottom segment 92A₁) are formed on exposed sidewalls of the nanostructures 54 and an exposed upper surface of the fin 66 (e.g., the substrate 50). In addition, each of the first epitaxial layers 92A may substantially cover entireties of the exposed sidewalls of the nanostructures 54 as well as the exposed upper surface of the fin 66. In some embodiments, the first epitaxial layers 92A may be formed beyond these surfaces to partially extend over the inner spacers 90.

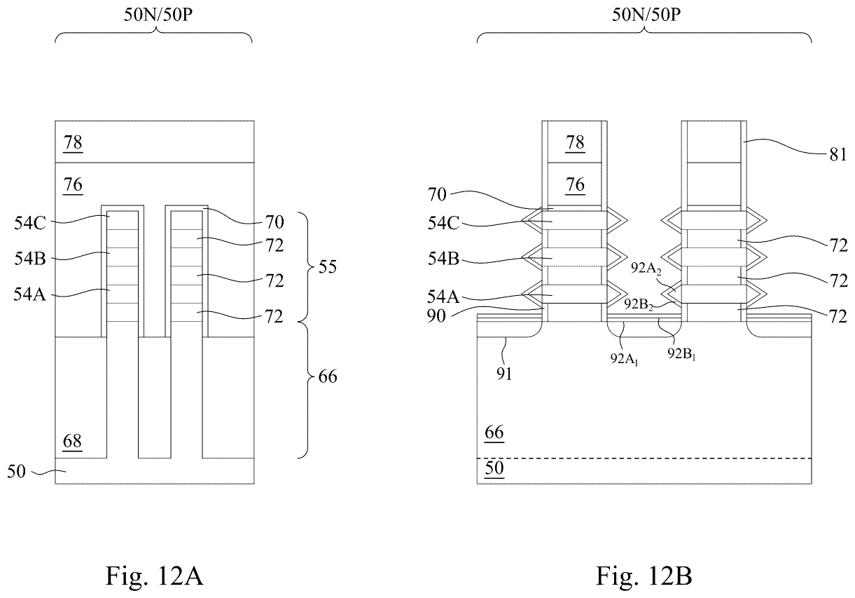

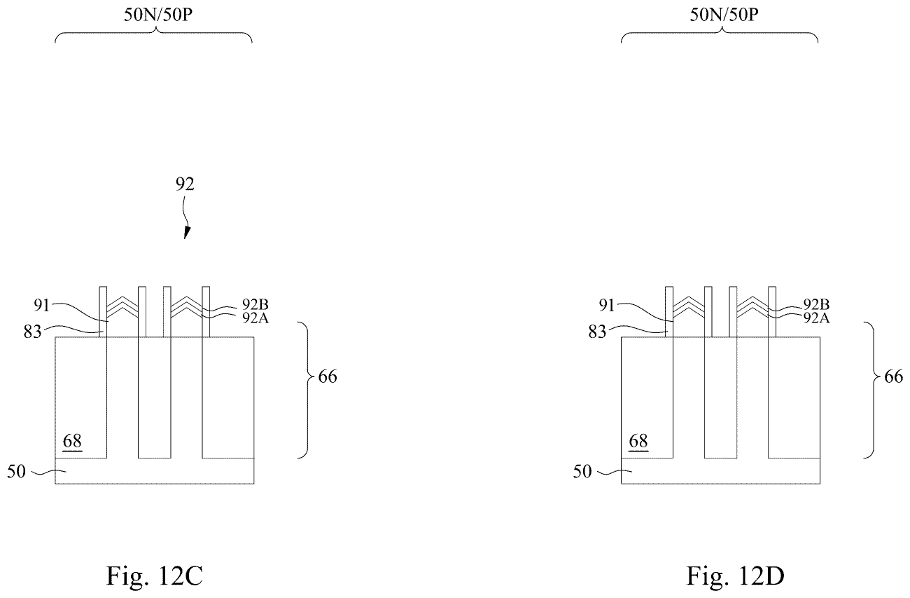

In FIGS. 12A-12D, a second epitaxial layer 92B is formed over the first epitaxial layer 92A in the first recesses 86. The second epitaxial layer 92B may comprise a boron-doped semiconductor. In regard to some nano-FETs (e.g., p-type nano-FETs), the second epitaxial layer 92B may comprise boron-doped silicon germanium (SiGeₓ:B, wherein 0.25≤x≤1). For example, the germanium concentration (in atomic percentage) may range from 20 at % to 60 at %, and the boron concentration may range from 1E20 atoms/cm³ to 2E21 atoms/cm³. Further, the second epitaxial layers 92B may be formed with a thickness ranging from 5 nm to 10 nm. In the n-type region 50N, the germanium concentration may be less (e.g., zero) and/or the boron concentration may be substantially the same or different.

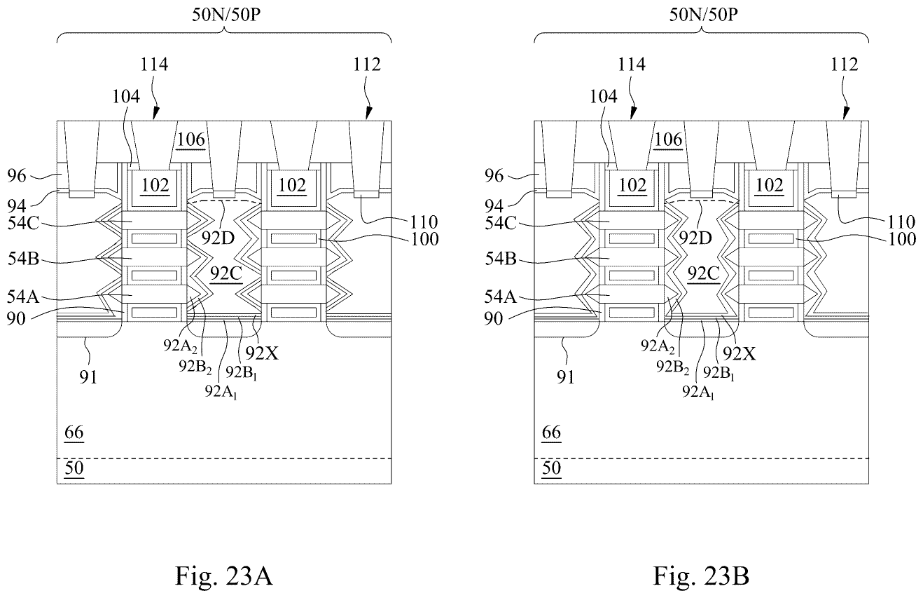

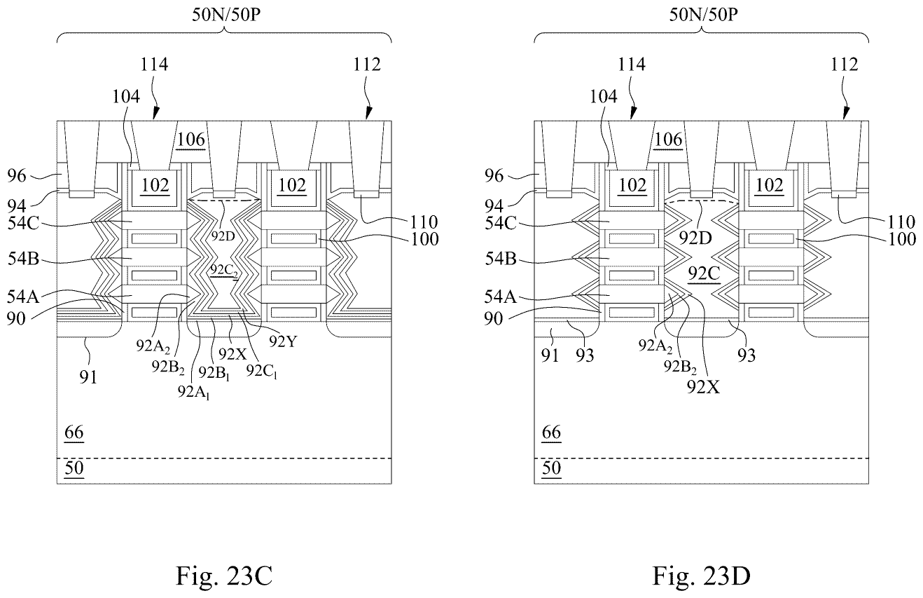

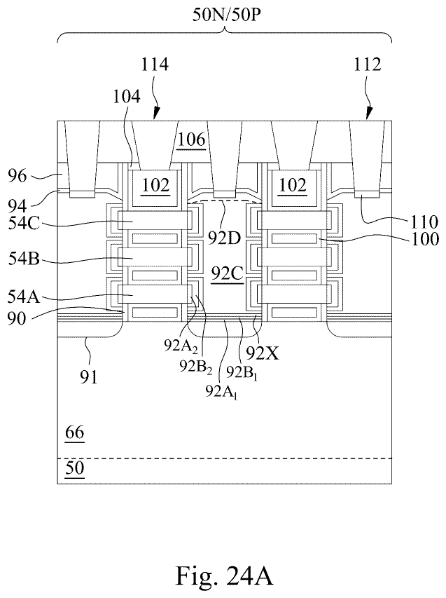

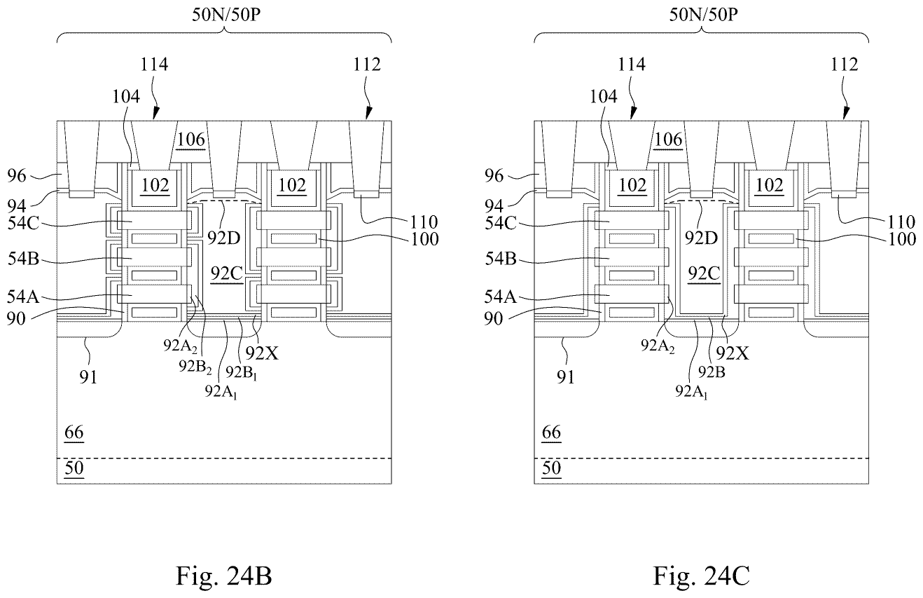

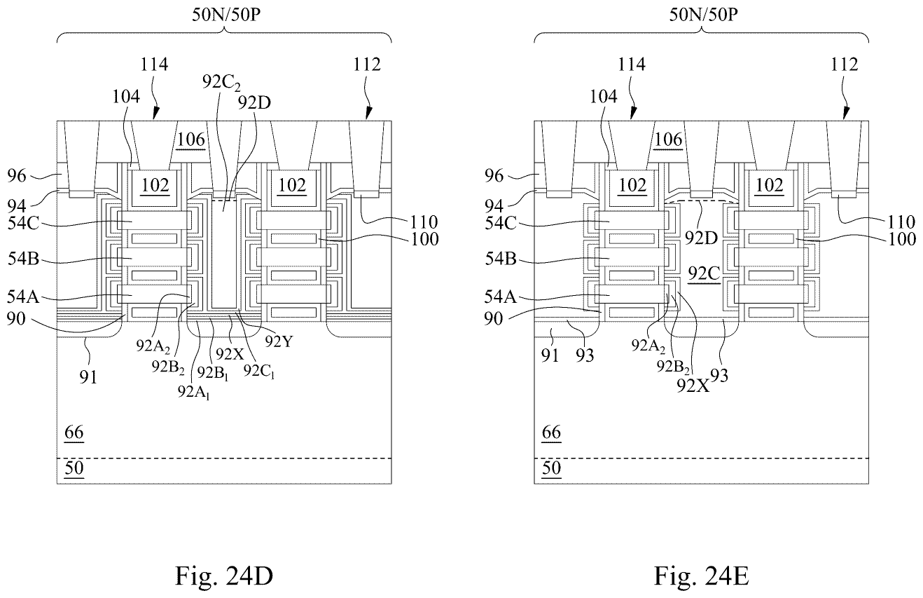

In some embodiments, the second epitaxial layer 92B may include a plurality of the second epitaxial layers 92B which are discontinuous from one another. In accordance with various other embodiments (see FIGS. 23A-24E), some or all of the second epitaxial layers 92B may be merged or continuous with one another. The second epitaxial layers 92B (e.g., sidewall segments 92B₂ and a bottom segment 92B₁) are formed on each of the distinct first epitaxial layers 92A (e.g., the sidewall segments 92A₂ and the bottom segment 92A₁) on the sidewalls of the nanostructures 54 and the upper surface of the fin 66 (e.g., the substrate 50). Note that each of the first epitaxial layers 92A (e.g., the sidewall segments 92A₂) and the corresponding second epitaxial layers 92B (e.g., the sidewall segments 92B₂) formed along the sidewalls of the nanostructures 54 may be referred to collectively as sidewall epitaxies of the epitaxial source/drain region 92. In addition, the first epitaxial layer 92A (e.g., the bottom segment 92A₁) and the second epitaxial layer 92B (e.g., the bottom segment 92B₁) along the upper surface of the fin 66 may be referred to collectively as a bottom epitaxy of the epitaxial source/drain region 92. As such, the sidewall epitaxies (including or excluding the bottom epitaxy, as applicable) may be fully discontinuous, partially discontinuous (e.g., partially continuous or partially merged), or fully continuous (e.g., fully merged).

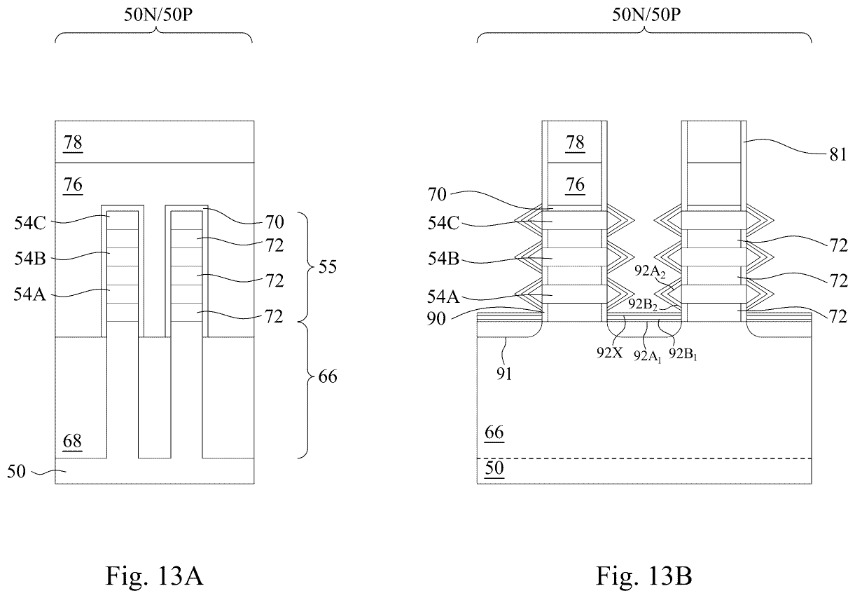

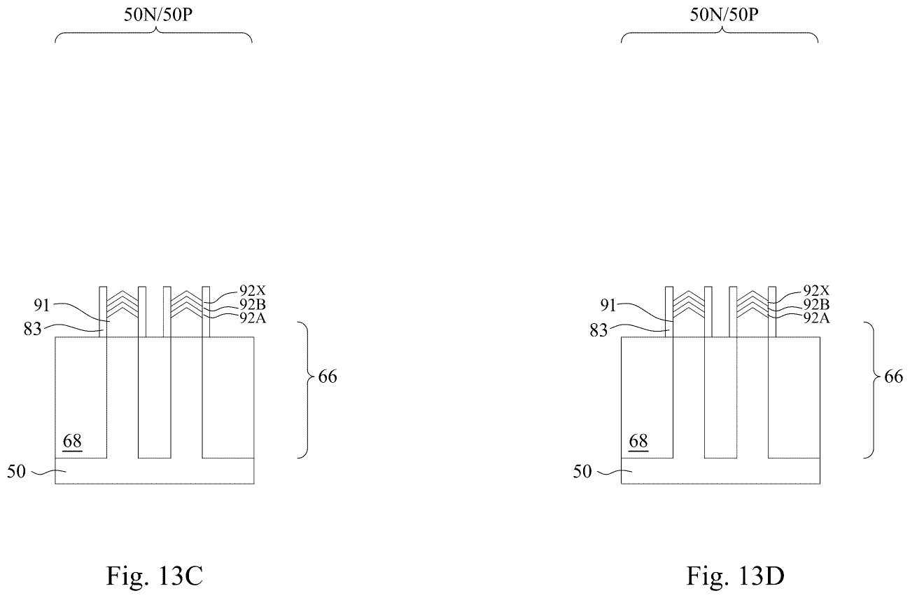

In FIGS. 13A-13D, a shape fixing layer 92X (e.g., a capping layer) is formed over the second epitaxial layer 92B for at least some nano-FETs (e.g., p-type nano-FETs). In accordance with various embodiments, the shape fixing layer 92X serves as a scaffolding layer which maintains its shape during subsequent steps in the formation of the epitaxial source/drain regions 92. As a result, the shape fixing layer 92X also helps to maintain the shape of the underlying second epitaxial layers 92B (e.g., the underlying sidewall epitaxies and bottom epitaxy).

In some embodiments, the shape fixing layer 92X may be a high boron-doped and low germanium epitaxial layer. The shape fixing layer 92X may comprise boron-doped silicon (Si:B) or boron-doped silicon germanium (SiGeₓ:B, wherein 0≤x≤0.25). For example, the germanium concentration may range from 0 at % to 20 at %, and the boron concentration may range from 7.0E20 atoms/cm³ to 5.0E21 atoms/cm³. In accordance with various embodiments, the germanium concentration of the shape fixing layer 92X may be lesser than the second epitaxial layer 92B. In addition, the boron concentration of the shape fixing layer 92X may be greater than the second epitaxial layer 92B (as well as the first epitaxial layer 92A).

As noted above, the shape fixing layer 92X may comprise boron-doped silicon or boron-doped silicon germanium. Boron-doped silicon may be used to form the shape fixing layer 92X to be a more rigid scaffold, while boron-doped silicon germanium may be used to form the shape fixing layer 92X with flexibility in direct relation to the concentration of germanium. For example, some smaller epitaxial source/drain regions 92 may benefit with the shape fixing layer 92X comprising boron-doped silicon because small changes (e.g., defects) in those epitaxial source/drain regions 92 may have larger effects on performance. In addition, the shape fixing layer 92X has an effect on the strain in the nanostructures 54, and such an effect is limited by the smaller overall size of the epitaxial source/drain region 92. On the other hand, some larger epitaxial source/drain regions 92 may benefit with the shape fixing layer 92X comprising boron-doped silicon germanium for greater flexibility in the shape fixing layer 92X, which limits the effect that the shape fixing layer 92X has on the strain in the nanostructures 54. As such, the nano-FETs may include different types of shape fixing layers 92X, such as comprising boron-doped silicon or boron-doped silicon germanium of varying boron and germanium concentrations based on the parameters described above.

In some embodiments, the shape fixing layer 92X may include a plurality of the shape fixing layers 92X which are discontinuous from one another. In accordance with various other embodiments (see FIGS. 23A-24E), some or all of the shape fixing layers 92X may be merged or continuous with one another, which may be based in part on whether the underlying sidewall epitaxies and bottom epitaxy are continuous. The shape fixing layers 92X are formed on each of the second epitaxial layers 92B (e.g., the sidewall epitaxies and the bottom epitaxy). Further, the shape fixing layers 92X may be formed with a thickness that is lesser than the second epitaxial layers 92B, such as ranging from 3 nm to 5 nm.

As noted above, the epitaxial source/drain regions 92 (e.g., the first epitaxial layers 92A and/or the second epitaxial layers 92B) may be formed to create a strain in the nanostructures 54 (e.g., channel regions of the nano-FETs). For example, the epitaxial source/drain regions 92 in the p-type regions 50P may create a compressive strain in the nanostructures 54. However, these epitaxial source/drain regions 92 may be deformed by heat in subsequent steps (e.g., further formation of the epitaxial source/drain regions 92 and later in the nano-FET fabrication process) in a phenomenon known as thermal reflow. The scaffolding support of the shape fixing layers 92X improves structural integrity of the sub-layers of the epitaxial source/drain regions 92 to ensure the compressive strain remains in the nanostructures 54. As a result, the epitaxial source/drain regions 92 may be free of thermal reflow defects, and the nano-FETs may be fabricated with greater yield and improved wafer acceptance testing (WAT) performance.

In various embodiments, the first epitaxial layer 92A has a first reflow temperature, the second epitaxial layer 92B has a second reflow temperature, and the shape fixing layer 92X has a third reflow temperature. Note that the reflow temperature of a material is the temperature at which a material melts or at which the material begins exhibiting at least some liquid properties. The third reflow temperature is greater than the second reflow temperature, which means that higher temperatures would be required to melt the material of the shape fixing layer 92X. In some embodiments, the third reflow temperature is also greater than the first reflow temperature. In addition, the first reflow temperature may be greater than the second reflow temperature.

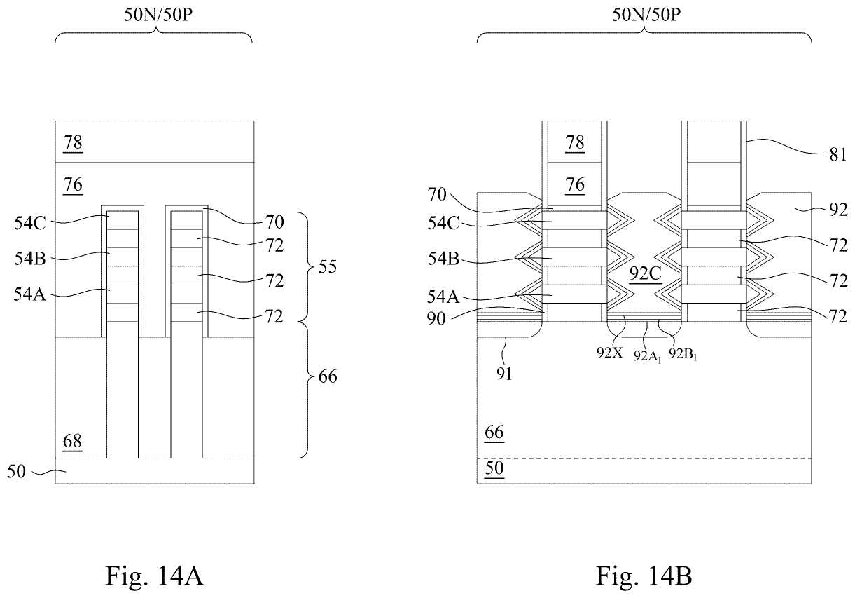

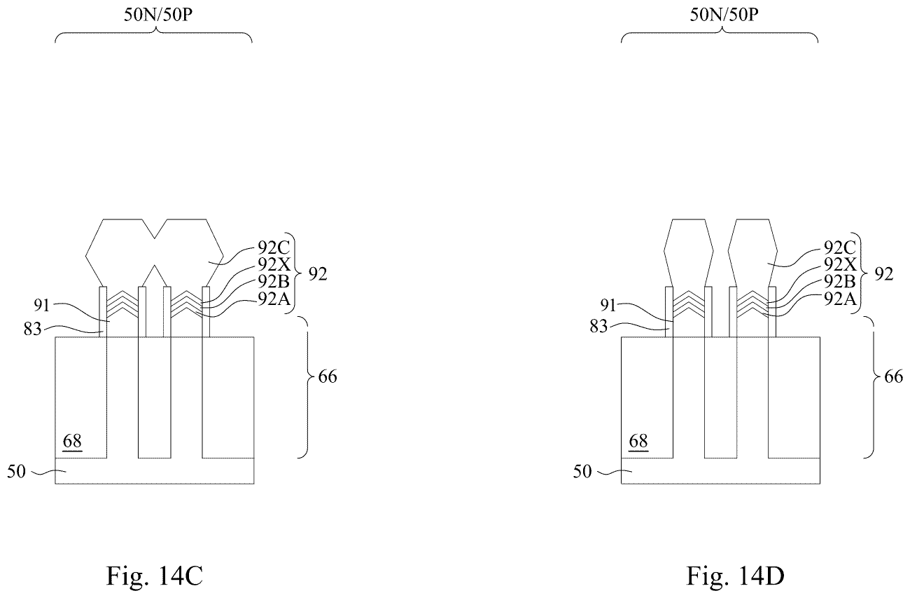

In FIGS. 14A-14D, a third epitaxial layer 92C is formed over the shape fixing layer 92X. In some embodiments, the third epitaxial layer 92C may be a bulk fill layer which connects or merges the shape fixing layers 92X of the epitaxial source/drain regions 92. In regard to some nano-FETs (e.g., p-type nano-FETs), the third epitaxial layer 92C may comprise boron-doped silicon germanium (SiGeₓ:B, wherein x≤1). The germanium concentration of the third epitaxial layer 92C may be greater than the shape fixing layer 92X and, optionally, lesser than the second epitaxial layer 92B. In addition, the boron concentration of the third epitaxial layer 92C may be lesser than the shape fixing layer 92X and, substantially the same as or less than the second epitaxial layer 92B.

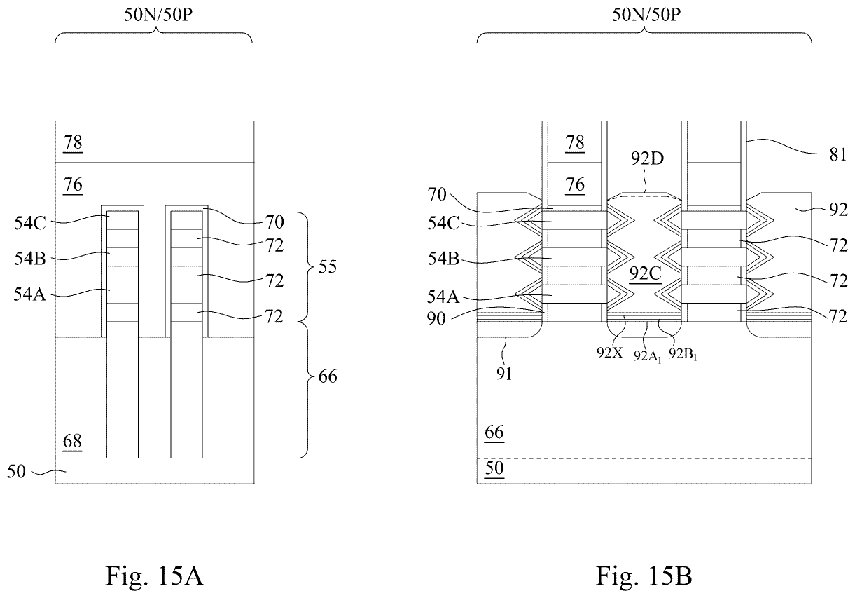

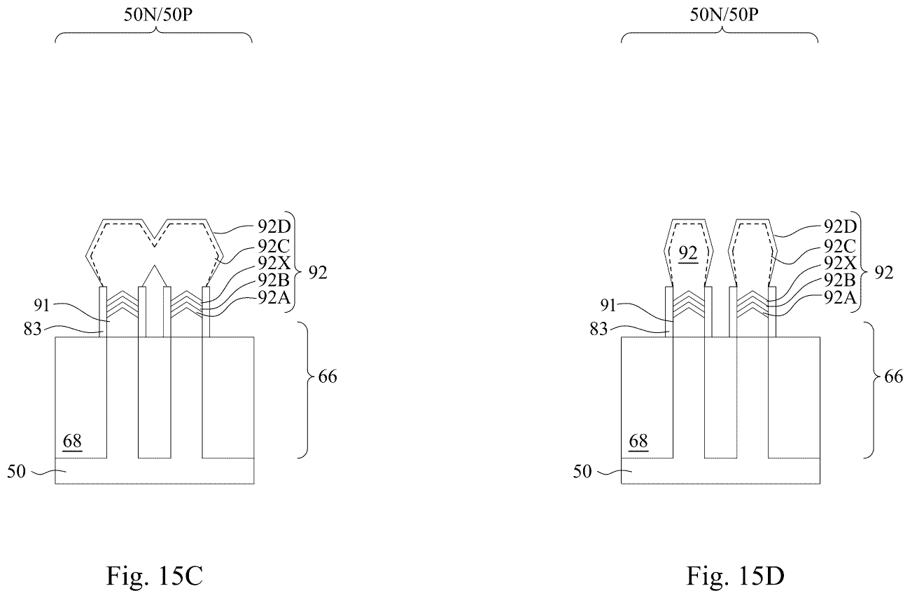

In FIGS. 15A-15D, a fourth epitaxial layer 92D is formed over the third epitaxial layer 92C. In some embodiments, the fourth epitaxial layer 92D may be a final layer (e.g., a capping layer) of the epitaxial source/drain region 92. The fourth epitaxial layer 92D may comprise boron-doped silicon or boron-doped silicon germanium with similar or lesser concentrations as described above in connection with the third epitaxial layer 92C.

As a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, these facets cause adjacent epitaxial source/drain regions 92 of a same nano-FET to merge as illustrated by FIG. 15C. In other embodiments, adjacent epitaxial source/drain regions 92 remain separated after the epitaxy process is completed as illustrated by FIG. 15D. In the embodiments illustrated in FIGS. 15C and 15D, the fin spacers 83 may be formed on top surfaces of the STI regions 68, thereby blocking the epitaxial growth. In some other embodiments, the fin spacers 83 may cover portions of the sidewalls of the nanostructures 55 further blocking the epitaxial growth. In some other embodiments, the fin spacers 83 may be omitted entirely, and the epitaxially grown region may extend to the top surface of the STI regions 68.

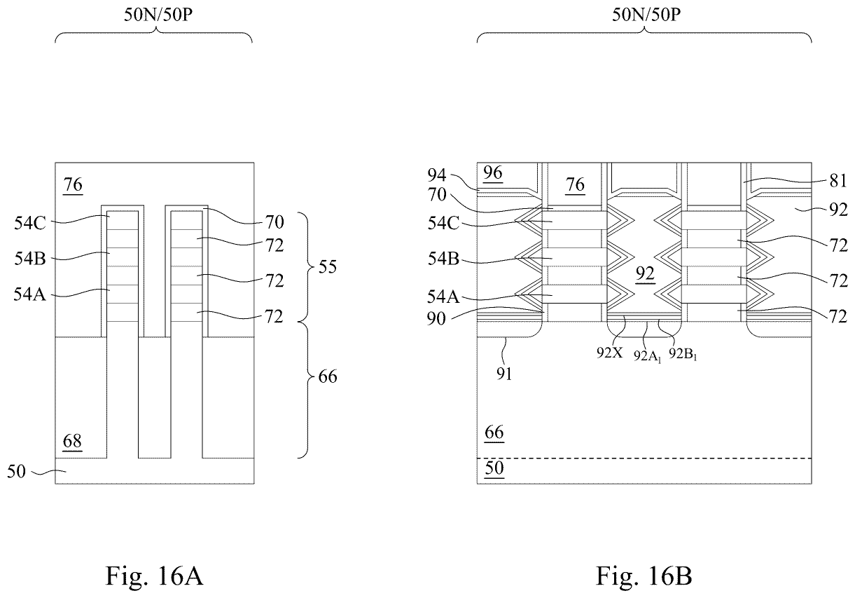

In FIGS. 16A and 16B, a first interlayer dielectric (ILD) 96 is deposited over the structure illustrated in FIGS. 15A and 15B, respectively. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the masks 78, and the gate spacers 81. The CESL 94 may comprise a dielectric material, such as, silicon nitride, silicon oxide, silicon oxynitride, or the like, having a different etch rate than the material of the overlying first ILD 96.

After the first ILD 96 is deposited, a planarization process, such as a CMP, may be performed to level the top surface of the first ILD 96 with the top surfaces of the dummy gates 76 (as shown) or the masks 78. The planarization process may also remove the masks 78 on the dummy gates 76, and portions of the gate spacers 81 along sidewalls of the masks 78. After the planarization process, top surfaces of the dummy gates 76, the gate spacers 81, and the first ILD 96 are level within process variations. Accordingly, the top surfaces of the dummy gates 76 are exposed through the first ILD 96. In some embodiments, the masks 78 may remain, in which case the planarization process levels the top surface of the first ILD 96 with top surface of the masks 78 and the gate spacers 81.

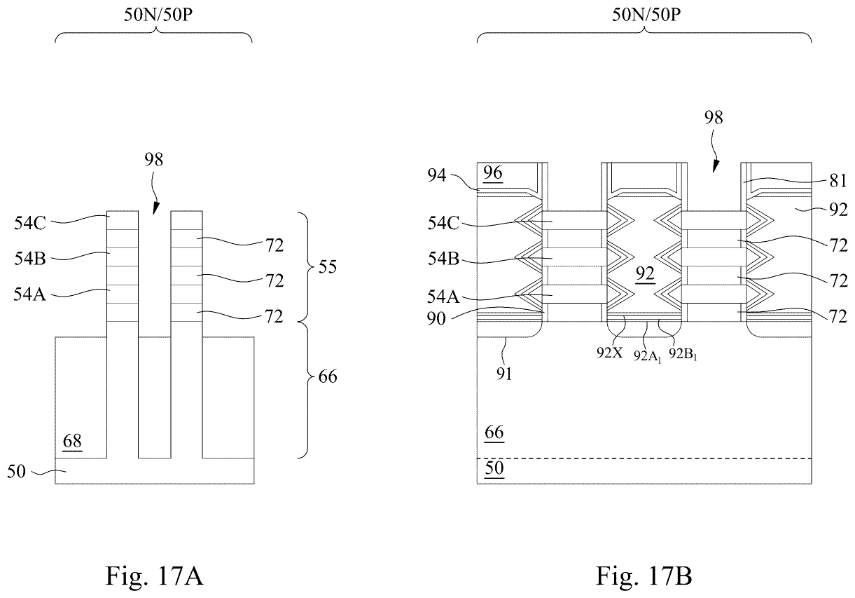

In FIGS. 17A and 17B, the dummy gates 76, and the masks 78 if present, are removed in one or more etching steps, so that second recesses 98 are formed. Portions of the dummy gate dielectrics 70 in the second recesses 98 may also be removed. In some embodiments, the dummy gates 76 and the dummy gate dielectrics 70 are removed by an anisotropic dry etch process. For example, the etching process may include a dry etch process using reaction gas(es) that selectively etch the dummy gates 76 at a faster rate than the first ILD 96 or the gate spacers 81. Each second recess 98 exposes and/or overlies portions of nanostructures 55, which act as channel regions in subsequently completed nano-FETs. Portions of the nanostructures 55 which act as the channel regions are disposed between neighboring pairs of the epitaxial source/drain regions 92. During the removal, the dummy gate dielectrics 70 may be used as etch stop layers when the dummy gates 76 are etched. The dummy gate dielectrics 70 may then be removed after the removal of the dummy gates 76.

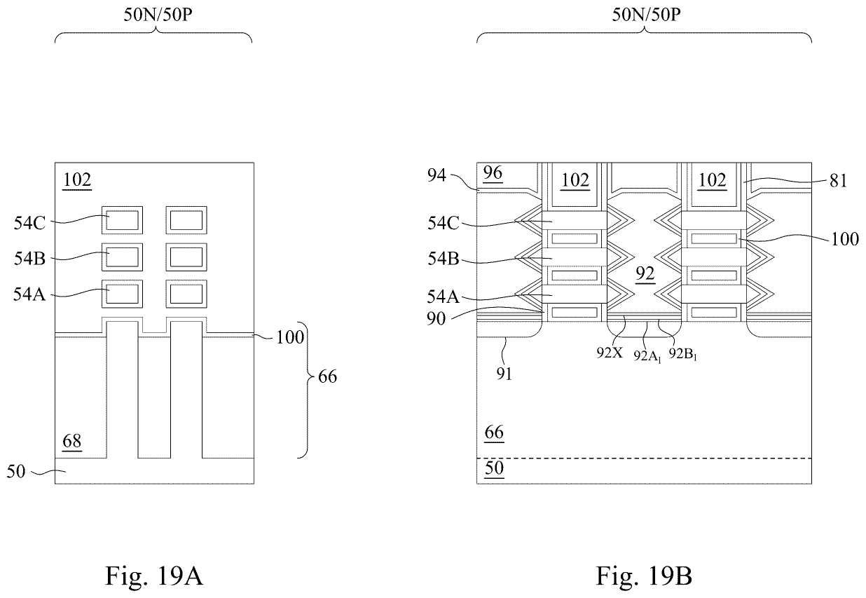

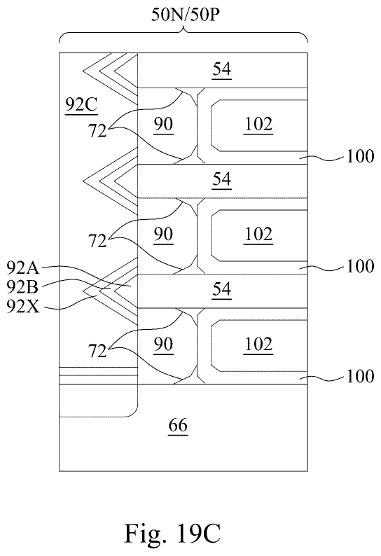

In FIGS. 18A and 18B, the sacrificial material 72 is removed, extending the second recesses 98. Removing the sacrificial material 72 may include performing an isotropic etching process such as wet etching or the like using etchants which are selective to the materials of the sacrificial material 72, while the second nanostructures 54 remain relatively unetched as compared to the sacrificial material 72. The sacrificial material 72 may be completely removed, or a residue of the sacrificial material 72 may remain on sidewalls of the inner spacers in the second recesses 98 (see e.g., FIG. 19C).

In some embodiments, the STI regions 68 may be etched while removing the sacrificial material 72, but the total amount of loss in the STI regions 68 may be reduced by controlling etching parameters (e.g., timing) while removing the sacrificial material 72. In other embodiments, the STI regions 68 may include a hard mask (not separately illustrated) at a top surface to protect the underlying STI regions 68 from etching while patterning and removing the sacrificial material 72. In such embodiments, the hard mask may comprise, for example, a nitride.

In FIGS. 19A-19C, gate dielectric layers 100 and gate electrodes 102 are formed for replacement gates. The gate dielectric layers 100 are deposited conformally in the second recesses 98. The gate dielectric layers 100 may be formed on top surfaces and sidewalls of the substrate 50 and on top surfaces, sidewalls, and bottom surfaces of the second nanostructures 54. The gate dielectric layers 100 may also be deposited on top surfaces of the first ILD 96, the CESL 94, the gate spacers 81, and the STI regions 68.

In accordance with some embodiments, the gate dielectric layers 100 comprise one or more dielectric layers, such as an oxide, a metal oxide, the like, or combinations thereof. For example, in some embodiments, the gate dielectrics may comprise a silicon oxide layer and a metal oxide layer over the silicon oxide layer. In some embodiments, the gate dielectric layers 100 include a high-k dielectric material, and in these embodiments, the gate dielectric layers 100 may have a k value greater than about 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, and the like.

The gate electrodes 102 are deposited over the gate dielectric layers 100, respectively, and fill the remaining portions of the second recesses 98. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 19A-19C, the gate electrodes 102 may comprise any number of liner layers, any number of work function tuning layers, and a fill material. Any combination of the layers which make up the gate electrodes 102 may be deposited in the n-type region 50N between adjacent ones of the second nanostructures 54 and between the second nanostructure 54A and the substrate 50, and may be deposited in the p-type region 50P between adjacent ones of the first nanostructures 52.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the second recesses 98, a planarization process, such as a CMP, may be performed to remove the excess portions of the gate dielectric layers 100 and the material of the gate electrodes 102, which excess portions are over the top surface of the first ILD 96. The remaining portions of material of the gate electrodes 102 and the gate dielectric layers 100 thus form replacement gate structures of the resulting nano-FETs. The gate electrodes 102 and the gate dielectric layers 100 may be collectively referred to as “gate structures.”

FIG. 19C illustrates a detailed view of various elements of FIG. 19B, including the epitaxial source/drain regions 92, the gate dielectric layers 100, the gate electrodes 102, the second nanostructures 54, and the inner spacers 90. In some embodiments, as illustrated by FIG. 19C, a residue of the sacrificial material 72 may remain on the inner spacers 90, such as between the inner spacers 90 and the gate dielectric layers 100/gate electrodes 102. For example, the sacrificial material 72 may not be fully removed, and the gate dielectric layers 100 may be formed on the remaining sacrificial material 72. Because the sacrificial material 72 is an insulating material (e.g., silicon oxide), the remaining residue may not significantly impact the electrical performance of the resulting device.

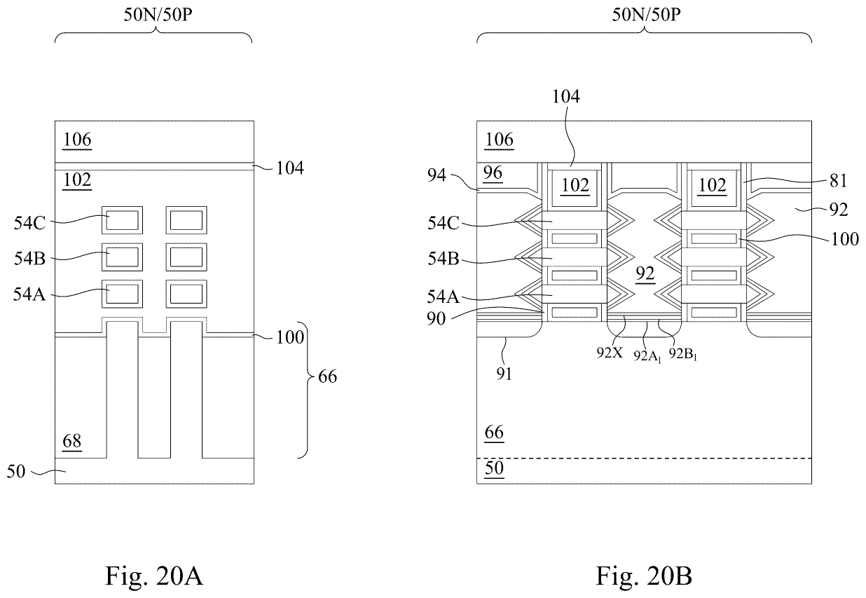

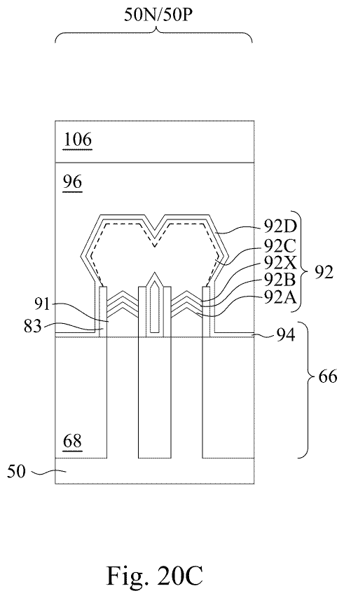

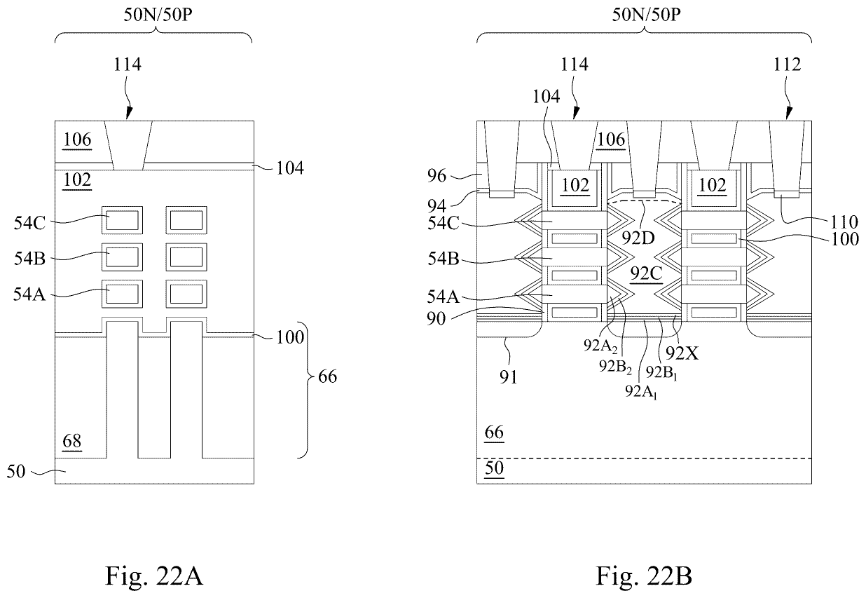

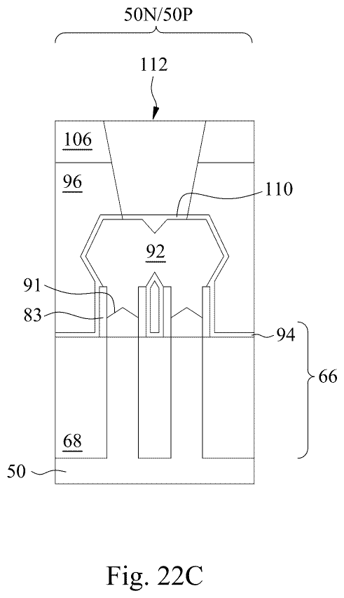

In FIGS. 20A-20C, the gate structure (including the gate dielectric layers 100 and the corresponding overlying gate electrodes 102) is recessed, so that a recess is formed directly over the gate structure and between opposing portions of gate spacers 81. A gate mask 104 comprising one or more layers of dielectric material, such as silicon nitride, silicon oxynitride, or the like, is filled in the recess, followed by a planarization process to remove excess portions of the dielectric material extending over the first ILD 96. Subsequently formed gate contacts (such as the gate contacts 114, discussed below with respect to FIGS. 22A-22C) penetrate through the gate mask 104 to contact the top surface of the recessed gate electrodes 102.

As further illustrated by FIGS. 20A-20C, a second ILD 106 is deposited over the first ILD 96 and over the gate mask 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like.

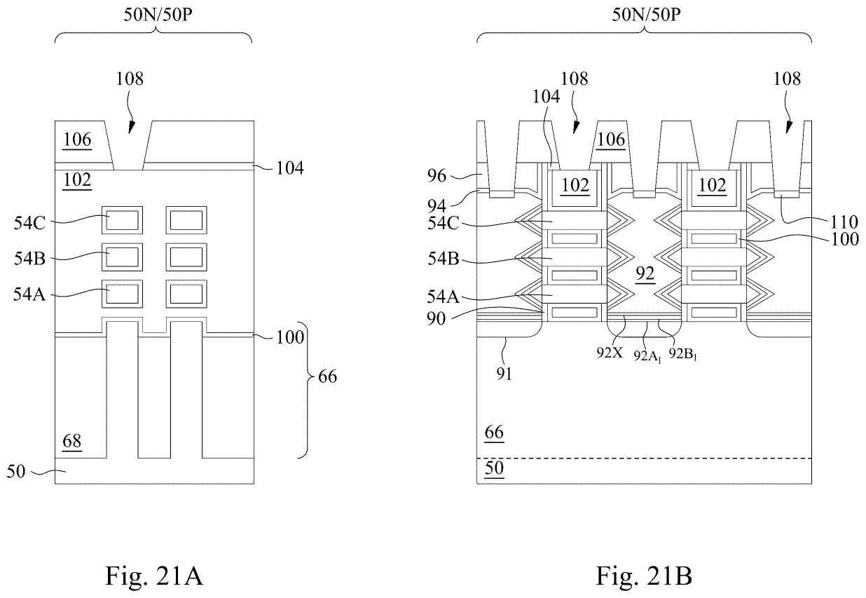

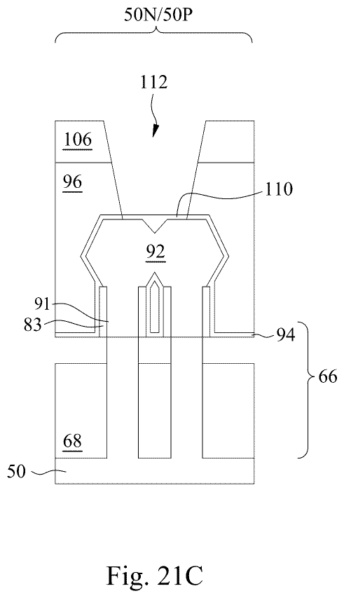

In FIGS. 21A-21C, the second ILD 106, the first ILD 96, the CESL 94, and the gate masks 104 are etched to form third recesses 108 exposing surfaces of the epitaxial source/drain regions 92 and/or the gate structure. The third recesses 108 may be formed by etching using an anisotropic etching process, such as RIE, NBE, or the like. In some embodiments, the third recesses 108 may be etched through the second ILD 106 and the first ILD 96 using a first etching process; may be etched through the gate masks 104 using a second etching process; and may then be etched through the CESL 94 using a third etching process. A mask, such as a photoresist, may be formed and patterned over the second ILD 106 to mask portions of the second ILD 106 from the first etching process and the second etching process. In some embodiments, the etching process may over-etch, and therefore, the third recesses 108 extend into the epitaxial source/drain regions 92 and/or the gate structure, and a bottom of the third recesses 108 may be level with (e.g., at a same level, or having a same distance from the substrate), or lower than (e.g., closer to the substrate) the epitaxial source/drain regions 92 and/or the gate structure. Although FIG. 21B illustrate the third recesses 1o8 as exposing the epitaxial source/drain regions 92 and the gate structure in a same cross section, in various embodiments, the epitaxial source/drain regions 92 and the gate structure may be exposed in different cross-sections, thereby reducing the risk of shorting subsequently formed contacts.

After the third recesses 108 are formed, silicide regions 110 are formed over the epitaxial source/drain regions 92. In some embodiments, the silicide regions 110 are formed by first depositing a metal (not shown) capable of reacting with the semiconductor materials of the underlying epitaxial source/drain regions 92 (e.g., silicon, silicon germanium, germanium) to form silicide or germanide regions. For example, metals such as nickel, cobalt, titanium, tantalum, platinum, tungsten, other noble metals, other refractory metals, rare earth metals or their alloys, may be used. The metal may be deposited over the exposed portions of the epitaxial source/drain regions 92. A thermal annealing process may then be utilized to form the silicide regions 110. The un-reacted portions of the deposited metal are then removed, e.g., by an etching process. Although silicide regions 110 are referred to as silicide regions, silicide regions 110 may also be germanide regions, or silicon germanide regions (e.g., regions comprising silicide and germanide). In an embodiment, the silicide region 110 comprises TiSi, and has a thickness in a range between about 2 nm and about 10 nm.

Next, in FIGS. 22A-22C, contacts 112 and 114 (may also be referred to as contact plugs) are formed in the third recesses 108. The contacts 112 and 114 may each comprise one or more layers, such as barrier layers, diffusion layers, and fill materials. For example, in some embodiments, the contacts 112 and 114 each include a barrier layer and a conductive material, and are electrically coupled to the underlying conductive feature (e.g., gate structure 102 and/or silicide region 110 in the illustrated embodiment). The contacts 114 are electrically coupled to the gate structure 102 and may be referred to as gate contacts, and the contacts 112 are electrically coupled to the silicide regions 110 and may be referred to as source/drain contacts. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 106.

FIGS. 23A-25B illustrate nano-FETs with various additional embodiments of the epitaxial source/drain regions 92. These embodiments (e.g., the epitaxial source/drain regions 92) may be formed similarly as described above unless otherwise stated. In accordance with various embodiments, the illustrated epitaxial source/drain regions 92 may be particular to p-type nano-FETs (e.g., formed in the p-type region 50P). It should be appreciated that any suitable combinations of these embodiments and the previously described embodiments may be utilized in an integrated circuit die.

FIGS. 23A-23D illustrate cross-sectional views of intermediate stages in the formation of nano-FETs after formation of epitaxial source/drain regions 92 wherein the sidewall epitaxies (e.g., the sidewall segments 92A₂/92B₂) have a triangle-triangle (e.g., double triangular) or substantial triangle-triangle growth pattern. Note that reference to triangular shapes herein may include generally three-sided shapes which are substantially triangular. In particular, in the illustrated cross-sections, the first epitaxial layer 92A and the second epitaxial layer 92B have triangular shapes extending from the sidewalls of the nanostructures 54. Each of the first epitaxial layers 92A may form with a triangular shape and each of the second epitaxial layers 92B may form with a triangular outline extending from a corresponding sidewall of the nanostructures 54. In addition, the first shape fixing layer 92X follows the triangular outlines of the second epitaxial layers 92B. In some embodiments, the triangle-triangle growth pattern may occur based, in part, on the crystal plane of the corresponding sidewalls of the nanostructures 54. For example, the sidewall epitaxies may form over [111] or [113] crystal surfaces.

In FIG. 23A, the epitaxial source/drain regions 92 include partially discontinuous epitaxies (e.g., the first epitaxial layers 92A and the second epitaxial layers 92B), which pertains to the bottom epitaxies (e.g., the bottom segments 92A₁/92B₁) and the sidewall epitaxies (e.g., the sidewall segments 92A₂/92B₂). For example, some (but not all) of the second epitaxial layers 92B may be merged or continuous with one another and/or with the bottom epitaxy (e.g., the bottom segments 92A₁/92B₁). As illustrated, the shape fixing layers 92X over the continuous sidewall epitaxies may also be continuous, while the shape fixing layers 92X over the discontinuous sidewall epitaxies may also be discontinuous. As such, some of the continuous second epitaxial layers 92B may merge over interposing inner spacers 90. On the other hand, some of the shape fixing layers 92X may extend to be adjacent to surfaces of inner spacers 90 between discontinuous sidewall epitaxies.

In FIG. 23B, the epitaxial source/drain regions 92 include fully continuous sidewall epitaxies (e.g., the first epitaxial layers 92A and the second epitaxial layer 92B). For example, the second epitaxial layer 92B may be one continuous layer as it connects all of the sidewall epitaxies to one another. As illustrated, the shape fixing layer 92X may also form as one continuous layer over an exposed surface of the second epitaxial layer 92B.

In FIG. 23C, the epitaxial source/drain regions 92 may include a first shape fixing layer 92X and a second shape fixing layer 92Y. In particular, the first epitaxial layer 92A, the second epitaxial layer 92B, and the first shape fixing layer 92X may be formed similarly as described above in connection with the fully discontinuous (see FIGS. 11A-15D), partially discontinuous (see FIG. 23A), and/or fully continuous (see FIG. 23B) layouts. However, the third epitaxial layer 92C may be formed in two portions wherein the second shape fixing layer 92Y is formed there-between.

In some embodiments, a primary third epitaxial sub-layer 92C₁ is formed over the first shape fixing layer 92X similarly as an incomplete version of the process described above in connection with forming the third epitaxial layer 92C. The primary third epitaxial sub-layer 92C₁ may merge the sidewall epitaxies (if not already merged by underlying layers). The second shape fixing layer 92Y is then formed over the primary third epitaxial sub-layer 92C₁ similarly as described above in connection with the shape fixing layer 92X. A secondary third epitaxial sub-layer 92C: is then formed over the second shape fixing layer 92Y similarly as a completion of the process described above in connection with forming the third epitaxial layer 92C. The fourth epitaxial layer 92D (e.g., the capping layer) may then be formed as the final portion of the epitaxial source/drain regions 92.

As illustrated, the primary third epitaxial sub-layer 92C₁ is a portion of the epitaxial source/drain region 92 interposed between the first shape fixing layer 92X and the second shape fixing layer 92Y. For example, the primary third epitaxial sub-layer 92C₁ may have a thickness ranging from 1 nm to 10 nm, such as from 2 nm to 3 nm. In addition, the second shape fixing layer 92Y may have a thickness ranging from 0.5 nm to 5 nm, such as from 3 nm to 5 nm. The secondary third epitaxial sub-layer 92C₂ then fills a remainder of the lateral space of the first recess 86.

In FIG. 23D, before forming the second epitaxial layer 92B, an underlayer dielectric 93 may be formed in the first recess 86 and over the semiconductor layer 91. The underlayer dielectric 93 provides greater insulation around the epitaxial source/drain regions 92 and may reduce leakage effects. The underlayer dielectric 93 may also be referred to as an isolation layer, a bottom isolation layer, or a flexible bottom isolation (FBI) layer. The underlayer dielectric 93 may be an oxide, such as silicon oxide, a nitride, the like, or a combination thereof, and may be formed by ALD or CVD, such as high-density plasma CVD (HDP-CVD), flowable CVD (FCVD), or the like, or combinations thereof. For example, acceptable dielectric materials may include silicon nitride, silicon oxynitride, silicon oxycarbonitride, silicon oxycarbide, silicon carbonitride, silicon oxide, aluminum oxide, hafnium oxide, or the like. In some embodiments, a dielectric material is deposited as described above and etched down to the desired dimensions to form the underlayer dielectric 93 in each of the first recesses 86.

As illustrated, the underlayer dielectric 93 may be in contact with first inner spacers 90 on lowermost segments of the sacrificial material 72 (or on lowermost nanostructures of the first nanostructures 52, if still present). Top surfaces of the underlayer dielectric 93 may be disposed below the top surfaces of these lowermost first inner spacers 90. The underlayer dielectric 93 may be separated from the second nanostructures 54. Although the underlayer dielectric 93 is illustrated as being above the top surfaces of the fins 66 as an example, the underlayer dielectric 93 may be disposed at other locations, such as below the top surfaces of the fins 66.

The first epitaxial layer 92A (e.g., the sidewall segments 92A₂) and remaining layers of the epitaxial source/drain regions 92 are then formed in the first recesses 86 over the underlayer dielectrics 93, similarly as described above in accordance with any of the previously described embodiments. Note that a bottom segment of the first epitaxial layer 92A may not form over the underlayer dielectric 93. However, as illustrated, it should be appreciated that the second epitaxial layer 92B substantially form on the exposed semiconductor surfaces. As such, the sidewall segments 92B₂ of the second epitaxial layer 92B may form on the sidewall segments 92A₂ of the first epitaxial layer 92A on the sidewalls of the nanostructures 54 without forming a bottom segment of the second epitaxial layer 92B in the first recess 86 due to presence of the underlayer dielectric 93. Moreover, various embodiments of the epitaxial source/drain regions 92 as being fully discontinuous, partially discontinuous, or fully continuous may be based on the sidewall epitaxies (e.g., the applicable segments of the first epitaxial layer 92A and the second epitaxial layer 92B) without regard to the bottom epitaxy which may not include bottom segments of the first or second epitaxial layers 92A/92B in embodiments which include the underlayer dielectric 93.

FIGS. 24A-24E illustrate cross-sectional views of intermediate stages in the formation of nano-FETs after formation of epitaxial source/drain regions 92 wherein the sidewall epitaxies have a rectangle-rectangle (e.g., double rectangular) or substantial rectangle-rectangle growth pattern. Note that reference to rectangular shapes herein may include quadrilateral-like shapes which are substantially rectangular. In particular, in the illustrated cross-sections, the first epitaxial layer 92A and the second epitaxial layer 92B have rectangular shapes extending from the sidewalls of the nanostructures 54. Each of the first epitaxial layers 92A may form with a rectangular shape and each of the second epitaxial layers 92B may form with a rectangular outline extending from a corresponding sidewall of the nanostructures 54. In addition, the first shape fixing layer 92X follows the rectangular outlines of the second epitaxial layers 92B. In some embodiments, the rectangle-rectangle growth pattern may occur based, in part, on the crystal plane of the corresponding sidewalls of the nanostructures 54. For example, the sidewall epitaxies may form over [110] crystal surfaces.

In FIG. 24A, the epitaxial source/drain regions 92 include fully discontinuous sidewall epitaxies (e.g., the first epitaxial layers 92A and the second epitaxial layers 92B). For example, all of the second epitaxial layers 92B may be discontinuous from one another and from the bottom epitaxy. As illustrated, the shape fixing layers 92X may also be discontinuous from one another. In some embodiments (not specifically illustrated), some or all of the sidewall epitaxies may be close enough to one another that some or all of the corresponding shape fixing layers 92X may be merged or continuous with one another.

In FIG. 24B, the epitaxial source/drain regions 92 include partially discontinuous sidewall epitaxies. For example, some (but not all) of the second epitaxial layers 92B may be merged or continuous with one another and/or with the bottom epitaxy. As illustrated, the shape fixing layers 92X over the continuous sidewall epitaxies may also be continuous, while the shape fixing layers 92X over the discontinuous sidewall epitaxies may also be discontinuous. As such, some of the continuous second epitaxial layers 92B may merge over interposing inner spacers 90. On the other hand, some of the shape fixing layers 92X may extend to be adjacent to surfaces of inner spacers 90 between discontinuous sidewall epitaxies.

In FIG. 24C, the epitaxial source/drain regions 92 include fully continuous sidewall epitaxies (e.g., the first epitaxial layers 92A and the second epitaxial layer 92B). For example, the second epitaxial layer 92B may be one continuous layer as it connects all of the sidewall epitaxies to one another. As illustrated, the shape fixing layer 92X may also form as one continuous layer over an exposed surface of the second epitaxial layer 92B.

In FIG. 24D, the epitaxial source/drain regions 92 may include a first shape fixing layer 92X and a second shape fixing layer 92Y. In particular, the first epitaxial layer 92A, the second epitaxial layer 92B, and the first shape fixing layer 92X may be formed similarly as described above in connection with the fully discontinuous (see FIGS. 11A-15D), partially discontinuous (see FIG. 23A), and/or fully continuous (see FIG. 23B) layouts. However, similarly as described above in connection with FIG. 23C, the third epitaxial layer 92C may be formed in two portions wherein the second shape fixing layer 92Y is formed there-between.

In some embodiments, a primary third epitaxial sub-layer 92C₁ is formed over the first shape fixing layer 92X similarly as an incomplete version of the process described above in connection with forming the third epitaxial layer 92C. The primary third epitaxial sub-layer 92C₁ may merge the sidewall epitaxies (if not already merged by underlying layers). The second shape fixing layer 92Y is then formed over the primary third epitaxial sub-layer 92C₁ similarly as described above in connection with the shape fixing layer 92X. A secondary third epitaxial sub-layer 92C₂ is then formed over the second shape fixing layer 92Y similarly as a completion of the process described above in connection with forming the third epitaxial layer 92C. The fourth epitaxial layer 92D (e.g., the capping layer) may then be formed as the final portion of the epitaxial source/drain regions 92.

For example, the primary third epitaxial sub-layer 92C₁ may have a thickness ranging from 2 nm to 3 nm, and the second shape fixing layer 92Y may have a thickness ranging from 3 nm to 5 nm (e.g., a portion of the epitaxial source/drain region 92 interposed between the first shape fixing layer 92X and the second shape fixing layer 92Y). The secondary third epitaxial sub-layer 92C₂ then fills a remainder of the lateral space of the first recess 86. Note that another iteration of sub-layers and shape fixing layers may be used in the third epitaxial layer 92C.

In FIG. 24E, an underlayer dielectric 93 may be formed in the first recess 86 along the exposed upper surface the fin 66 (e.g., the substrate 50) before forming the epitaxial source/drain regions 92. Similarly as described above in connection with FIG. 23D, the underlayer dielectric 93 may be an oxide, such as silicon oxide, a nitride, the like, or a combination thereof, and may be formed by high-density plasma CVD (HDP-CVD), flowable CVD (FCVD), the like, or a combination thereof. In some embodiments, a dielectric material is deposited as described above and etched down to the desired dimensions to form the underlayer dielectric 93 in each of the first recesses 86.

The epitaxial source/drain regions 92 are formed in the first recesses 86 over the underlayer dielectrics 93 similarly as described above in accordance with any of the previously described embodiments. However, as illustrated, it should be appreciated that the first epitaxial layer 92A substantially forms on the exposed semiconductor surfaces. As such, the first epitaxial layer 92A may form on the sidewalls of the nanostructures 54 without forming on the upper surfaces of the fins 66, which are covered by the underlayer dielectric 93. Moreover, various embodiments of the epitaxial source/drain regions 92 as being fully discontinuous, partially discontinuous, or fully continuous may be based on the sidewall epitaxies without regard to the bottom epitaxy which may not form in embodiments with the underlayer dielectric 93.

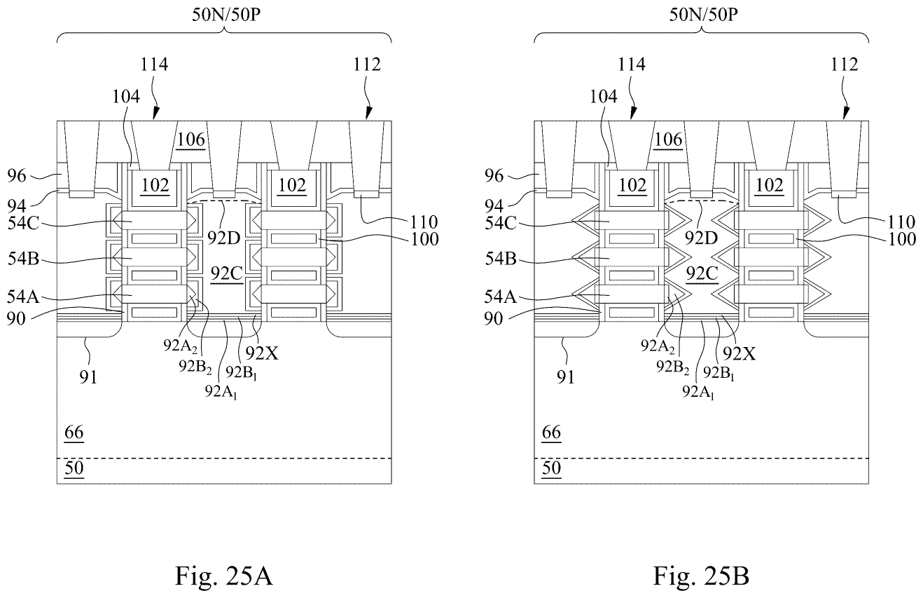

FIGS. 25A and 25B illustrate cross-sectional views in which each of the sidewall epitaxies includes both triangular and rectangular shapes. For example, FIG. 25A illustrates the first epitaxial layer 92A having a triangular shape while the second epitaxial layer 92B has a rectangular outline extending from the sidewalls of the nanostructures 54. In addition, FIG. 25B illustrates the first epitaxial layer 92A having a rectangular shape while the second epitaxial layer 92B has a triangular outline extending from the sidewalls of the nanostructures 54. In some embodiments, the respective triangle-rectangle growth patterns may occur based, in part, on the crystal planes of the corresponding sidewalls of the nanostructures 54. For example, triangular portions of the sidewall epitaxies may form over [111] or [113] crystal surfaces, and rectangular portions of the sidewall epitaxies may form over [110] crystal surfaces.

Although FIGS. 25A and 25B are each illustrated as having epitaxial source/drain regions 92 with fully discontinuous sidewall epitaxies, it should be appreciated that other embodiments discussed above may include either of these triangle-rectangle growth patterns. For example, the epitaxial source/drain regions 92 may have partially discontinuous or fully continuous sidewall epitaxies. In addition, the epitaxial source/drain regions 92 may include only the first shape fixing layer 92X or further include the second shape fixing layer 92Y.

Various advantages are achieved. In particular, a nano-FET is formed with an epitaxial source/drain 92 comprising a plurality of sub-layers. After forming one or two of the sub-layers (e.g., sidewall epitaxies comprising the first epitaxial layer 92A and the second epitaxial layer 92B), a shape fixing layer 92X is formed to provide internal structural support to the epitaxial source/drain region 92. One or two additional sub-layers (e.g., the third epitaxial layer 92C and the fourth epitaxial layer 92D) may then be formed over the shape fixing layer 92X. The support provided by the shape fixing layer 92X ensures that the sidewall epitaxies maintain their shapes (e.g., preventing thermal reflow) during subsequent process steps involving elevated temperatures. As a result, the channel regions (e.g., the nanostructures 54) of the nano-FET retain the desired stress to be fabricated at a greater yield and with an improved performance.

In an embodiment, a method includes: forming a plurality of semiconductor layers over a substrate, the plurality of semiconductor layers comprising alternating first semiconductor layers and second semiconductor layers; patterning the plurality of the semiconductor layers into a fin; etching the fin to form a first recess; forming an epitaxial region in the first recess, forming the epitaxial region comprising: forming first epitaxial layers over sidewalls of the second semiconductor layers; forming second epitaxial layers over the first epitaxial layers; forming shape fixing layers over the second epitaxial layers; and forming a bulk epitaxial layer over the shape fixing layers; removing the first semiconductor layers to form a second recess between the second semiconductor layers; and forming a gate structure in the second recess. In another embodiment, the second epitaxial layers have a first germanium concentration and a first boron concentration, wherein the shape fixing layers have a second germanium concentration and a second boron concentration, and wherein the second boron concentration is greater than the first boron concentration. In another embodiment, the first boron concentration ranges from 1E20 to 1E21, and wherein the second boron concentration ranges from 7E20 to 5E21. In another embodiment, the second germanium concentration is lesser than the first germanium concentration. In another embodiment, the first germanium concentration ranges from 20 atomic percent to 60 atomic percent, and wherein the second germanium concentration ranges from 0% atomic percent to 20% atomic percent. In another embodiment, the second epitaxial layers are discontinuous from one another. In another embodiment, a first set of the second epitaxial layers is continuous with one another, and wherein a second set of the second epitaxial layers is discontinuous from one another. In another embodiment, the second epitaxial layers are continuous with one another.

In an embodiment, a method includes: forming a stack of alternating first semiconductor layers and second semiconductor layers over a substrate; patterning the stack into a fin; forming a gate structure across the fin; etching a recess in the fin adjacent to the gate structure; replacing the first semiconductor layers with dielectric layers; forming sidewall epitaxies in the recess along sidewalls of the second semiconductor layers, each of the sidewall epitaxies comprising a first epitaxial layer and a second epitaxial layer; forming a third epitaxial layer over the second epitaxial layer, a reflow temperature of the third epitaxial layer being greater than a reflow temperature of the second epitaxial layer; and forming a fourth epitaxial layer over the third epitaxial layer, wherein a source/drain region comprises the sidewall epitaxies, the third epitaxial layer, and the fourth epitaxial layer. In another embodiment, the second epitaxial layer comprises a second boron concentration, wherein the third epitaxial layer comprises a third boron concentration, and wherein the third boron concentration is greater than the second boron concentration. In another embodiment, a second germanium concentration of the second epitaxial layer is greater than a third germanium concentration of the third epitaxial layer. In another embodiment, the first epitaxial layer comprises boron-doped silicon, wherein the second epitaxial layer comprises boron-doped silicon germanium, and wherein the third epitaxial layer comprises boron-doped silicon. In another embodiment, at least one of the sidewall epitaxies comprises: a first portion of the first epitaxial layer in contact with a first layer of the second semiconductor layers; a second portion of the first epitaxial layer in contact with a second layer of the second semiconductor layers; and a third portion of the second epitaxial layer being in contact with the first portion and the second portion. In another embodiment, the sidewall epitaxies comprise a fully continuous sidewall epitaxy.

In an embodiment, a semiconductor device includes: a first nanostructure disposed over a substrate; a second nanostructure disposed over the first nanostructure; a gate structure between the substrate and the first nanostructure and between the first nanostructure and the second nanostructure; a source/drain region disposed over the substrate and laterally adjacent to the first nanostructure and the second nanostructure, the source/drain region comprising: a first epitaxial layer adjacent to and in contact with the first nanostructure; a second epitaxial layer adjacent to and in contact with the second nanostructure, the first epitaxial layer and the second epitaxial layer having a substantially same composition; a third epitaxial layer adjacent to and in contact with the first epitaxial layer, the third epitaxial layer having a third germanium concentration; a fourth epitaxial layer adjacent to and in contact with the third epitaxial layer, the fourth epitaxial layer having a fourth germanium concentration, the third germanium concentration being greater than the fourth germanium concentration; and a fifth epitaxial layer adjacent to and in contact with the fourth epitaxial layer, the fifth epitaxial layer having a fifth germanium concentration, the fifth germanium concentration being greater than the fourth germanium concentration. In another embodiment, a boron concentration of the fourth epitaxial layer is greater than a boron concentration of the third epitaxial layer. In another embodiment, a reflow temperature of the fourth epitaxial layer is greater than a reflow temperature of the third epitaxial layer. In another embodiment, the third epitaxial layer is in physical contact with the second epitaxial layer. In another embodiment, the semiconductor device further includes an inner spacer, wherein in a cross-section, the inner spacer is bounded by the first nanostructure, the second nanostructure, the gate structure, and the source/drain region. In another embodiment, the fourth epitaxial layer is in contact with the inner spacer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a plurality of semiconductor layers over a substrate, the plurality of semiconductor layers comprising alternating first semiconductor layers and second semiconductor layers;
patterning the plurality of the semiconductor layers into a fin;
etching the fin to form a first recess;
forming an epitaxial region in the first recess, forming the epitaxial region comprising:
forming first epitaxial layers over sidewalls of the second semiconductor layers;
forming second epitaxial layers over the first epitaxial layers;
forming shape fixing layers over the second epitaxial layers; and
forming a bulk epitaxial layer over the shape fixing layers;
removing the first semiconductor layers to form a second recess between the second semiconductor layers; and
forming a gate structure in the second recess.

2. The method of claim 1, wherein the second epitaxial layers have a first germanium concentration and a first boron concentration, wherein the shape fixing layers have a second germanium concentration and a second boron concentration, and wherein the second boron concentration is greater than the first boron concentration.

3. The method of claim 2, wherein the first boron concentration ranges from 1E20 to 1E21, and wherein the second boron concentration ranges from 7E20 to 5E21.

4. The method of claim 2, wherein the second germanium concentration is lesser than the first germanium concentration.

5. The method of claim 4, wherein the first germanium concentration ranges from 20 atomic percent to 60 atomic percent, and wherein the second germanium concentration ranges from 0% atomic percent to 20% atomic percent.

6. The method of claim 1, wherein the second epitaxial layers are discontinuous from one another.

7. The method of claim 1, wherein a first set of the second epitaxial layers is continuous with one another, and wherein a second set of the second epitaxial layers is discontinuous from one another.

8. The method of claim 1, wherein the second epitaxial layers are continuous with one another.

9. A method comprising:
forming a stack of alternating first semiconductor layers and second semiconductor layers over a substrate;
patterning the stack into a fin;
forming a gate structure across the fin;
etching a recess in the fin adjacent to the gate structure;
replacing the first semiconductor layers with dielectric layers;
forming sidewall epitaxies in the recess along sidewalls of the second semiconductor layers, each of the sidewall epitaxies comprising a first epitaxial layer and a second epitaxial layer;
forming a third epitaxial layer over the second epitaxial layer, a reflow temperature of the third epitaxial layer being greater than a reflow temperature of the second epitaxial layer; and
forming a fourth epitaxial layer over the third epitaxial layer, wherein a source/drain region comprises the sidewall epitaxies, the third epitaxial layer, and the fourth epitaxial layer.

10. The method of claim 9, wherein the second epitaxial layer comprises a second boron concentration, wherein the third epitaxial layer comprises a third boron concentration, and wherein the third boron concentration is greater than the second boron concentration.

11. The method of claim 10, wherein a second germanium concentration of the second epitaxial layer is greater than a third germanium concentration of the third epitaxial layer.

12. The method of claim 10, wherein the first epitaxial layer comprises boron-doped silicon, wherein the second epitaxial layer comprises boron-doped silicon germanium, and wherein the third epitaxial layer comprises boron-doped silicon.

13. The method of claim 9, wherein at least one of the sidewall epitaxies comprises:
a first portion of the first epitaxial layer in contact with a first layer of the second semiconductor layers;
a second portion of the first epitaxial layer in contact with a second layer of the second semiconductor layers; and
a third portion of the second epitaxial layer being in contact with the first portion and the second portion.

14. The method of claim 9, wherein the sidewall epitaxies comprise a fully continuous sidewall epitaxy.

15. A semiconductor device comprising:
a first nanostructure disposed over a substrate;
a second nanostructure disposed over the first nanostructure;
a gate structure between the substrate and the first nanostructure and between the first nanostructure and the second nanostructure;
a source/drain region disposed over the substrate and laterally adjacent to the first nanostructure and the second nanostructure, the source/drain region comprising:
a first epitaxial layer adjacent to and in contact with the first nanostructure;
a second epitaxial layer adjacent to and in contact with the second nanostructure, the first epitaxial layer and the second epitaxial layer having a substantially same composition;
a third epitaxial layer adjacent to and in contact with the first epitaxial layer, the third epitaxial layer having a third germanium concentration;
a fourth epitaxial layer adjacent to and in contact with the third epitaxial layer, the fourth epitaxial layer having a fourth germanium concentration, the third germanium concentration being greater than the fourth germanium concentration; and
a fifth epitaxial layer adjacent to and in contact with the fourth epitaxial layer, the fifth epitaxial layer having a fifth germanium concentration, the fifth germanium concentration being greater than the fourth germanium concentration.

16. The semiconductor device of claim 15, wherein a boron concentration of the fourth epitaxial layer is greater than a boron concentration of the third epitaxial layer.

17. The semiconductor device of claim 15, wherein a reflow temperature of the fourth epitaxial layer is greater than a reflow temperature of the third epitaxial layer.

18. The semiconductor device of claim 15, wherein the third epitaxial layer is in physical contact with the second epitaxial layer.

19. The semiconductor device of claim 15, further comprising an inner spacer, wherein in a cross-section, the inner spacer is bounded by the first nanostructure, the second nanostructure, the gate structure, and the source/drain region.

20. The semiconductor device of claim 19, wherein the fourth epitaxial layer is in contact with the inner spacer.
